(19) United States
(12) Patent Application Publication
(10) Pub. No.: US 2026/0173731 A1
(43) Pub. Date: Jun. 18, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Chunyang LIU, Hefei (CN); Hung-Chih YU, Hefei (CN); Jen-Yu LEE, Hefei (CN)

(73) Assignees: Hefei Visionox Technology Co., Ltd., Hefei (CN); Visionox Technology Inc., Kunshan (CN)

(21) Appl. No.: 19/420,554

(22) Filed: Dec. 15, 2025

Related U.S. Application Data
(63) Continuation of application No. PCT/CN2025/130156, filed on Oct. 27, 2025.

(30) Foreign Application Priority Data
Dec. 13, 2024 (CN) 202411846566.6

(51) Int. Cl. H10K 59/80; H10K 59/12; H10K 59/122

(52) U.S. Cl. CPC H10K 59/873; H10K 59/1201; H10K 59/122; H10K 59/8723

(57) ABSTRACT

Disclosed are a display panel and a display device. A ratio of an area of an orthogonal projection of a first encapsulation unit on a base plate to a perimeter of an orthogonal projection of a first isolation opening on the base plate is a first ratio. A ratio of an area of an orthogonal projection of a second encapsulation unit on the base plate to a perimeter of an orthogonal projection of a second isolation opening on the base plate is a second ratio. A ratio of an area of an orthogonal projection of a third encapsulation unit on the base plate to a perimeter of an orthogonal projection of a third isolation opening on the base plate is a third ratio. The first ratio is less than or equal to a sum of the second ratio and the third ratio.

### CROSS-REFERENCE TO RELATED APPLICATIONS

This application is a continuation of International Application No. PCT/CN2025/130156, filed on Oct. 27, 2025, which claims priority to Chinese Patent Application No. 2024118465666, filed on Dec. 13, 2024. The disclosures of the aforementioned applications are hereby incorporated by reference in their entireties.

### FIELD

The present disclosure generally relates to the field of display technologies, and in particular, to a display panel and a display device.

### BACKGROUND

Organic Light Emitting Diodes (OLEDs) and flat-panel display devices based on technologies such as Light Emitting Diodes (LEDs) and the like have become a mainstream of display panels owing to advantages like high image quality, low power consumption, slim profile, and broad applicability, and are now widely used in various consumer electronic products such as mobile phones, televisions, notebook computers, desktop computers. In traditional display panel manufacturing processes, light-emitting pixel patterning is typically achieved using Fine Metal Mask (FMM). FMM technology is mature and has extensive mass production experience. However, FMM technology also has limitations such as limited precision, high development costs, and long development cycles. Fine Metal Mask Free technology may eliminate the limitations of traditional OLED processes on display size, resolution, and other panel performance characteristics, offering advantages of high performance, full-size capability, and agile delivery. Relevant content of the Fine Metal Mask Free technology are disclosed in Patents CN118251982A, CN115666161A, CN116648095A, CN117062489A, CN118678742A, CN118785761A, CN115224220A, CN118678729A, CN118660529A, and CN118660589A, which may be referred to for reference.

However, the display panel still faces several issues needed to be addressed urgently.

### SUMMARY

To overcome shortcomings in the prior art mentioned above, the present disclosure aims to provide a display panel. The display panel includes a base plate; an isolation structure, located on a side of the base plate, where a plurality of isolation opening are defined by the isolation structure, the plurality of isolation openings include a first isolation opening, a second isolation opening, and a third isolation opening, an area of an orthogonal projection of the first isolation opening on the base plate is larger than an area of an orthogonal projection of the second isolation opening on the base plate, and an area of an orthogonal projection of the first isolation opening on the base plate is larger than an area of an orthogonal projection of the third isolation opening on the base plate; a plurality of light-emitting units, where the plurality of light-emitting units include a first light-emitting unit, a second light-emitting unit, and a third light-emitting unit, at least part of the first light-emitting unit is located in the first isolation opening, at least part of the second light-emitting unit is located in the second isolation opening, and at least part of the third light-emitting unit is located in the third isolation opening; and a plurality of encapsulation units, where the plurality of encapsulation units include a first encapsulation unit, a second encapsulation unit, and a third encapsulation unit, the first encapsulation unit is located on a side, facing away from the base plate, of the first light-emitting unit, the second encapsulation unit is located on a side, facing away from the base plate, of the second light-emitting unit, and the third encapsulation unit is located on a side, facing away from the base plate, of the third light-emitting unit; where a ratio of an area of an orthogonal projection of the first encapsulation unit on the base plate to a perimeter of the orthogonal projection of the first isolation opening on the base plate is a first ratio, a ratio of an area of an orthogonal projection of the second encapsulation unit on the base plate to a perimeter of the orthogonal projection of the second isolation opening on the base plate is a second ratio, a ratio of an area of an orthogonal projection of the third encapsulation unit on the base plate to a perimeter of the orthogonal projection of the third isolation opening on the base plate is a third ratio, and the first ratio is less than or equal to a sum of the second ratio and the third ratio.

In some possible implementations, the present disclosure further provides a display panel. The display panel includes a base plate; an isolation structure, located on a side of the base plate, where the isolation structure includes a first isolation portion and a second isolation portion sequentially stacked along a direction away from the base plate, a plurality of isolation openings are defined by the second isolation portion, the plurality of isolation openings include a first isolation opening, a second isolation opening, and a third isolation opening, an area of an orthogonal projection of the first isolation opening on the base plate is larger than an area of an orthogonal projection of the second isolation opening on the base plate, the area of the orthogonal projection of the first isolation opening on the base plate is larger than an area of an orthogonal projection of the third isolation opening on the base plate; a plurality of light-emitting units, where the plurality of light-emitting units include a first light-emitting unit, a second light-emitting unit, and a third light-emitting unit, at least part of the first light-emitting unit is located in the first isolation opening, at least part of the second light-emitting unit is located in the second isolation opening, and at least part of the third light-emitting unit is located in the third isolation opening; and a plurality of encapsulation units, where the plurality of encapsulation units include a first encapsulation unit, a second encapsulation unit, and a third encapsulation unit, the first encapsulation unit is located on a side, facing away from the base plate, of the first light-emitting unit, the second encapsulation unit is located on a side, facing away from the base plate, of the second light-emitting unit, and the third encapsulation unit is located on a side, facing away from the base plate, of the third light-emitting unit; where a ratio of an area of the first encapsulation unit to an area of an overlapping region between the first encapsulation unit and the isolation structure is a fourth ratio, a ratio of an area of the second encapsulation unit to an area of an overlapping region between the second encapsulation unit and the isolation structure is a fifth ratio, a ratio of an area of the third encapsulation unit to an area of an overlapping region between the third encapsulation unit and the isolation structure is a sixth ratio, and the fourth ratio is less than or equal to a sum of the fifth ratio and the sixth ratio.

In some possible implementations, the present disclosure further provides a display panel. The display panel includes a base plate, an isolation structure, a light-emitting unit, and an encapsulation unit. The isolation structure is located on a side of the base plate, where the isolation structure comprises a first isolation portion and a second isolation portion sequentially stacked along a direction away from the base plate, the second isolation portion encloses to form an isolation opening. The light-emitting unit is at least partially located in the isolation opening. The encapsulation unit is located on a side, facing away from the base plate, of the light-emitting unit. Where a ratio of an area of an orthogonal projection of the encapsulation unit on the base plate to a perimeter of an orthogonal projection of the corresponding isolation opening of the encapsulation unit on the base plate is less than or equal to 50.

In some possible implementations, the present disclosure further provides a display panel. The display panel includes a base plate, an isolation structure, a light-emitting unit, and an encapsulation unit. The isolation structure is located on a side of the base plate, where the isolation structure comprises a first isolation portion and a second isolation portion sequentially stacked along a direction away from the base plate, the second isolation portion encloses to form an isolation opening. The light-emitting unit is at least partially located in the isolation opening. The encapsulation unit is located on a side, facing away from the base plate, of the light-emitting unit. Where an area of the encapsulation unit to an area of overlap between the encapsulation unit and the isolation structure is less than or equal to 50.

In some possible implementations, the present disclosure further provides a manufacturing method for the display panel. The method includes: providing a base plate; forming an isolation structure on a side of the base plate, where the isolation structure encloses to form an isolation opening, the isolation opening includes a first isolation opening, a second isolation opening, and a third isolation opening, an area of an orthogonal projection of the first isolation opening on the base plate is larger than an area of an orthogonal projection of the second isolation opening on the base plate, an area of an orthogonal projection of the first isolation opening on the base plate is larger than an area of an orthogonal projection of the third isolation opening on the base plate; forming at least a part of a light-emitting unit in the isolation opening, where the light-emitting unit includes a first light-emitting unit, a second light-emitting unit, and a third light-emitting unit, where the first light-emitting unit is at least partially located in the first isolation opening, the second light-emitting unit is at least partially located in the second isolation opening, and the third light-emitting unit is at least partially located in the third isolation opening; forming an encapsulation unit on a side, facing away from the base plate, of the light-emitting unit, where the encapsulation unit includes a first encapsulation unit, a second encapsulation unit, and a third encapsulation unit, where the first encapsulation unit is located on a side, facing away form the base plate, of the first light-emitting unit, the second encapsulation unit is located on a side, facing away form the base plate, of the second light-emitting unit, the third encapsulation unit is located on a side, facing away form the base plate, of the third light-emitting unit. Where a ratio of an area of an orthogonal projection of the first encapsulation unit on the base plate to a perimeter of an orthogonal projection of the first isolation opening on the base plate is a first ratio, a ratio of an area of an orthogonal projection of the second encapsulation unit on the base plate to a perimeter of an orthogonal projection of the second isolation opening on the base plate is a second ratio, a ratio of an area of an orthogonal projection of the third encapsulation unit on the base plate to a perimeter of an orthogonal projection of the third isolation opening on the base plate is a third ratio, the first ratio is less than or equal to a sum of the second ratio and the third ratio.

In some possible implementations, the present disclosure further provides a display device. The display device includes the display panel as described in the present disclosure, or includes the display panel obtained by the manufacturing method for the display panel described in the present disclosure.

The present disclosure has the following beneficial effects:
The present disclosure provides a display panel, a manufacturing method for the display panel and a display device. By setting the first ratio to be less than or equal to the sum of the second ratio and the third ratio, a stability of the first encapsulation unit may be enhanced, making the first encapsulation unit less likely to fall off, thereby improving the packaging effect of the first encapsulation unit on the first light-emitting unit, and enhancing the display effect of the display panel.

### BRIEF DESCRIPTION OF THE DRAWINGS

To illustrate technical solutions of embodiments of the present disclosure more clearly, a brief description of accompanying drawings that are required in the embodiments will hereinafter be provided. It should be understood that the accompanying drawings described below are only some embodiments of the present disclosure and should not be regarded as a limitation on the scope. For those skilled in the art, other drawings may be obtained based on these accompanying drawings without creative labor.

FIG. 1 is a partial top view of a display panel according to an embodiment of the present disclosure.

FIG. 2 is a schematic cross-sectional view taken along line A-A in FIG. 1 according to an embodiment of the present application.

FIG. 3 is a partial top view of a display panel according to another embodiment of the present disclosure.

FIG. 4 is a schematic cross-sectional view taken along line B-B in FIG. 3 according to an embodiment of the present application.

FIG. 5 is a schematic cross-sectional view taken along line B-B in FIG. 3 according to another embodiment of the present application.

FIG. 6 is a schematic cross-sectional view taken along line B-B in FIG. 3 according to still another embodiment of the present application.

FIG. 7 is a partial top view of a display panel according to an embodiment of the present disclosure.

FIG. 8 is a schematic cross-sectional view taken along line C-C in FIG. 7 according to an embodiment of the present application.

FIG. 9a is a partial top view of a display panel according to an embodiment of the present disclosure.

FIG. 9b is a schematic cross-sectional view taken along line D-D in FIG. 9a according to an embodiment of the present application.

FIG. 10a is partial top view of a display panel according to an embodiment of the present disclosure.

FIG. 10b is a schematic cross-sectional view taken along line M-M in FIG. 10a according to an embodiment of the present application.

FIG. 11 is partial top view of a display panel according to an embodiment of the present disclosure.

FIG. 12 is a schematic cross-sectional view taken along line E-E in FIG. 11 according to an embodiment of the present application.

FIG. 13 is partial top view of a display panel according to an embodiment of the present disclosure.

FIG. 14 is a schematic cross-sectional view taken along line F-F in FIG. 13 according to an embodiment of the present application.

FIG. 15 is a schematic cross-sectional view taken along line A-A in FIG. 1 according to an embodiment of the present application.

FIG. 16 is a schematic cross-sectional view taken along line A-A in FIG. 1 according to an embodiment of the present application.

FIG. 17 is partial top view of a display panel according to an embodiment of the present disclosure.

FIG. 18 is partial top view of a display panel according to an embodiment of the present disclosure.

FIG. 19 is partial top view of a display panel according to an embodiment of the present disclosure.

FIG. 20 is a schematic flowchart of a manufacturing method for a display panel according to an embodiment of the present disclosure.

FIG. 21 is a schematic cross-sectional view of sequentially forming a pixel-defining material layer and an isolation material layer on a side of a base plate according to an embodiment of the present disclosure.

FIG. 22 is a schematic cross-sectional view of after patterning an isolation material layer and a pixel material layer sequentially according to an embodiment of the present disclosure.

FIG. 23 is a schematic flowchart of a manufacturing method for a display panel according to another embodiment of the present disclosure.

### DETAILED DESCRIPTION OF THE EMBODIMENTS

To make objectives, technical solutions and advantages of embodiments of the present disclosure more clearly, a clear and complete description of technical solutions of the embodiments of the present disclosure will be provided in combination with the accompanying drawings in the embodiments of the present disclosure. Apparently, the described embodiments are a part rather than all of the embodiments of the present disclosure. The components of the embodiments of the present disclosure described and illustrated in the accompanying drawings can typically be arranged and designed in various different configurations.

Therefore, the detailed description of the embodiments of the present disclosure provided in the accompanying drawings is not intended to limit the scope of the present disclosure as claimed, but merely represents selected embodiments of the present disclosure. Based on the embodiments in the present disclosure, all other embodiments obtained by those of ordinary skill in the art without making inventive effort are within the scope of protection of the present disclosure.

It should be noted that similar reference numbers and letters in the accompanying drawings denote similar items, and thus once an item is defined in one accompanying drawing, it does not need to be further defined and explained in the subsequent accompanying drawings.

In the description of the present disclosure, it should be noted that the terms “center”, “up”, “down”, “vertical”, “horizontal”, “in”, “out”, and the like indicate an orientation or positional relationship based on an orientation or positional relationship shown in the accompanying drawings, or an orientation or positional relationship that is commonly adopted when a product of the invention is in use. These terms are used merely for the convenience of describing the present application and simplifying the description, rather than indicating or implying that the device or component must have a specific orientation, be constructed and operated in a specific orientation. Therefore, these terms should not be construed as limitations on the present application. In addition, the terms “first”, “second”, “third”, and so on are used solely for the purpose of distinguishing descriptions and should not be understood as indicating or implying relative importance.

It should be noted that different features in the embodiments of the present disclosure may be combined with each other without conflict.

A key approach to enhancing display quality is to increase a density of light-emitting units (i.e., pixel density) in a display panel. Currently, display panels manufactured using fine metal mask (FMM) technology are constrained by technical limitations that prevent further increases in the pixel density of light-emitting units. Through prolonged research, the inventors have discovered that to address the technical challenge of limited pixel density, an isolation structure can be incorporated into certain display panels. This structure allows a light-emitting function layer and a second electrode to be disconnected at the isolation structure during a full-surface deposition process. By performing multiple cycles of deposition and etching (i.e., patterning of light-emitting units), light-emitting units of different colors can be formed within distinct isolation openings.

A display panel in relative technologies may include a base plate, an isolation structure located on a side of the base plate, a light-emitting unit located in an isolation opening defined by the isolation structure, and an encapsulation unit located on a side, facing away from the base plate, of the light-emitting unit. The encapsulation unit is configured to encapsulate the light-emitting unit.

However, after long-term research, the inventors found that the encapsulation unit of the display panel in the relative technologies is prone to falling off, thereby affecting an encapsulation effect of the encapsulation unit on the light-emitting unit, making the light-emitting unit more likely to form dark spots, and ultimately affecting a display effect of the display panel.

To solve the above-mentioned technical problems, the inventors designed the following technical solutions innovatively. Specific implementations of the present disclosure will be described in detail below with reference to the accompanying drawings. It should be noted that the shortcomings of the solutions in the related art mentioned above are conclusions drawn by the inventors based on practical experience and careful research. Therefore, the process of discovering the above-mentioned technical problems and the solutions proposed by the present embodiment to resolve the above-mentioned problems should be regarded as the contributions made by the inventors during the inventive process of the present disclosure, and should not be construed as content well-known to those skilled in the art.

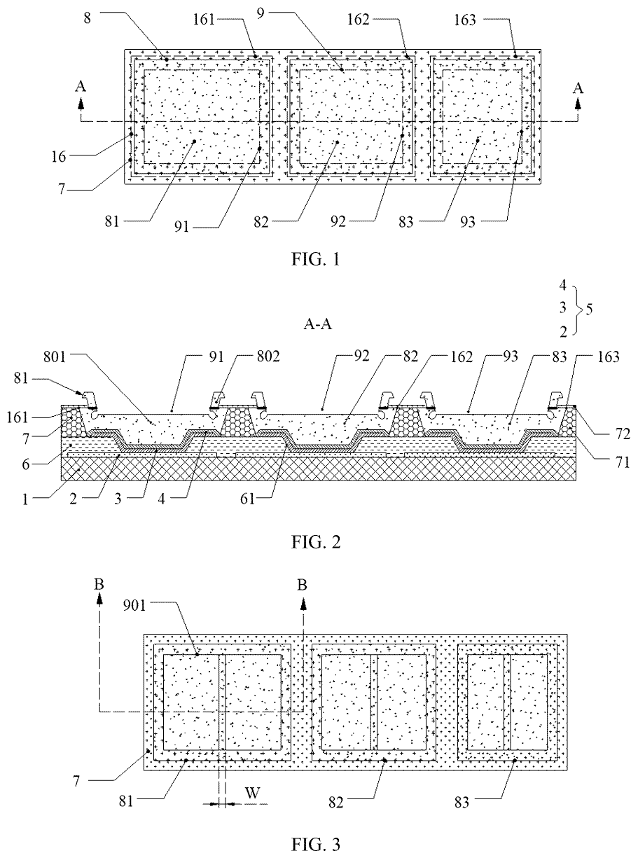

Referring to FIG. 1 and FIG. 2, the present embodiment provides a display panel. The display panel includes a base plate 1, an isolation structure 7, a plurality of light-emitting units 5, and a plurality of encapsulation units 8.

The isolation structure 7 is located on a side of the base plate 1. A plurality of isolation openings 9 are defined by the isolation structure 7. The plurality of isolation openings 9 include a first isolation opening 91, a second isolation opening 92, and a third isolation opening 93. An area of an orthogonal projection of the first isolation opening 91 on the base plate 1 is larger than an area of an orthogonal projection of the second isolation opening 92 on the base plate 1, and the area of the orthogonal projection of the first isolation opening 91 on the base plate 1 is larger than an area of an orthogonal projection of the third isolation opening 93 on the base plate 1. Therein, the orthogonal projection of the first isolation opening 91 on the base plate 1 is an opening formed by an orthogonal projection of the isolation structure 7 corresponding to the first isolation opening 91 on the base plate 1, the orthogonal projection of the second isolation opening 92 on the base plate 1 is an opening formed by an orthogonal projection of the isolation structure 7 corresponding to the second isolation opening 92 on the base plate 1, and the orthogonal projection of the third isolation opening 93 on the base plate 1 is an opening formed by an orthogonal projection of the isolation structure 7 corresponding to the third isolation opening 93 on the base plate 1.

The plurality of light-emitting units 5 include a first light-emitting unit, a second light-emitting unit, and a third light-emitting unit. At least part of the first light-emitting unit is located in the first isolation opening 91, at least part of the second light-emitting unit is located in the second isolation opening 92, and at least part of the third light-emitting unit is located in the third isolation opening 93.

The plurality of encapsulation units 8 include a first encapsulation unit 81, a second encapsulation unit 82, and a third encapsulation unit 83. The first encapsulation unit 81 is located on a side, facing away from the base plate 1, of the first light-emitting unit, the second encapsulation unit 82 is located on a side, facing away from the base plate 1, of the second light-emitting unit, and the third encapsulation unit 83 is located on a side, facing away from the base plate 1, of the third light-emitting unit.

Therein, a ratio of an area of an orthogonal projection of the first encapsulation unit 81 on the base plate 1 to a perimeter of the orthogonal projection of the first isolation opening 91 on the base plate 1 is a first ratio, a ratio of an area of an orthogonal projection of the second encapsulation unit 82 on the base plate 1 to a perimeter of the orthogonal projection of the second isolation opening 92 on the base plate 1 is a second ratio, and a ratio of an area of an orthogonal projection of the third encapsulation unit 83 on the base plate 1 to a perimeter of the orthogonal projection of the third isolation opening 93 on the base plate 1 is a third ratio. The first ratio is less than or equal to a sum of the second ratio and the third ratio.

Light emitted by the first light-emitting unit, the second light-emitting unit, and the third light-emitting unit is different from each other in color. For example, a color of light emitted by the first light-emitting unit includes red, a color of light emitted by the second light-emitting unit includes green, and a color of light emitted by the third light-emitting unit includes blue. Generally, the area of the orthogonal projection of the first isolation opening 91 corresponding to the first light-emitting unit on the base plate 1 is larger than both the area of the orthogonal projection of the second isolation opening 92 corresponding to the second light-emitting unit on the base plate 1 and the area of the orthogonal projection of the third isolation opening 93 corresponding to the third light-emitting unit on the base plate 1.

The larger an area of the isolation opening 9 is, the larger an area of the encapsulation unit 8 covering the isolation opening 9 is. Therefore, generally, the area of the orthogonal projection of the first encapsulation unit 81 on the base plate 1 is greater than both the area of the orthogonal projection of the second encapsulation unit 82 and the area of the orthogonal projection of the third encapsulation unit 83 on the base plate 1.

A larger area for the encapsulation unit 8 leads to greater external scouring forces and a higher probability of detachment. Therefore, the first encapsulation unit 81 typically experiences greater external scouring force than the second encapsulation unit 82 and the third encapsulation unit 83, and the first encapsulation unit 81 is relatively more likely to fall off compared with the second encapsulation unit 82 and the third encapsulation unit 83.

In addition, a larger perimeter for the orthogonal projection of the isolation opening 9 on the base plate 1 leads to a greater contact area between the encapsulation unit 8 and the isolation structure 7, stronger adhesive force between the encapsulation unit 8 and the isolation structure 7, and less possibility for the encapsulation unit 8 to fall off.

In view of above, stability of the encapsulation unit 8 is related to the perimeter of the orthogonal projection of the isolation opening 9 on the base plate 1, as well as the area of the orthogonal projection of the encapsulation unit 8 on the base plate 1.

After a long-term research, the inventors found that in the display panel, stability of the second encapsulation unit 82 and the third encapsulation unit 83 is relatively better than stability of the first encapsulation unit 81, and the second encapsulation unit 82 and the third encapsulation unit 83 are less likely to fall off under the external force. Therefore, based on the second encapsulation unit 82 and the third encapsulation unit 83, when the ratio of the area of the orthogonal projection of the first encapsulation unit 81 on the base plate 1 to the perimeter of the orthogonal projection of the first isolation opening 91 on the base plate 1 is less than or equal to, a sum of the ratio of the area of the orthogonal projection of the second encapsulation unit 82 on the base plate 1 to the perimeter of the orthogonal projection of the second isolation opening 92 on the base plate 1, and the ratio of the area of the orthogonal projection of the third encapsulation unit 83 on the base plate 1 to the perimeter of the orthogonal projection of the third isolation opening 93 on the base plate 1, that is, when the first ratio is less than or equal to a sum of the second ratio and the third ratio, the stability of the first encapsulation unit 81 may be ensured, thereby enabling the first encapsulation unit 81 to provide better encapsulation effect for the first light-emitting unit. As a result, the first light-emitting unit is less likely to develop dark spots, thereby improving a display effect of the display panel.

Based on the above design, in the present embodiment, by setting the first ratio to be less than or equal to the sum of the second ratio and the third ratio, the stability of the first encapsulation unit 81 may be improved, making the first encapsulation unit 81 less likely to fall off, enhancing the encapsulation effect of the first encapsulation unit 81 on the first light-emitting unit, thereby improving the display effect of the display panel.

In some possible implementations, the first ratio is greater than the second ratio, and the first ratio is greater than the third ratio.

In some possible implementations, referring to FIG. 1 and FIG. 2 again, a ratio of an area of an orthogonal projection of the encapsulation unit 8 on the base plate 1 to a perimeter of an orthogonal projection of an isolation opening 9 corresponding to the encapsulation unit 8 on the base plate 1 is less than or equal to 50. For example, the ratio may be 50, 45, 40, 35, 30, 25, 20, or 15, etc. By reasonably setting this ratio, the stability of the encapsulation unit 8 may be improved, making the encapsulation unit 8 less likely to fall off.

The ratio of the area of the orthogonal projection of the encapsulation unit 8 on the base plate 1 to the perimeter of the orthogonal projection of the corresponding isolation opening 9 of the encapsulation unit 8 on the base plate 1 may be less than or equal to 35. For example, the ratio may be 35, 30, 25, 20, or 15, etc. By reasonably setting this ratio, the stability of the encapsulation unit 8 may further be improved, making the encapsulation unit 8 less likely to fall off.

At least part of the encapsulation unit 8 extends from a side, facing the isolation opening 9, of the isolation structure 7, to a side, facing away from the base plate 1, of the isolation structure 7. The encapsulation unit 8 includes an edge encapsulating portion 802 and an encapsulation portion 801 connected to each other. The edge encapsulating portion 802 is located on a side, facing away from the base plate 1, of the isolation structure 7. The encapsulation portion 801 is located in the isolation opening 9. A ratio of an area of an orthogonal projection of the encapsulation portion 801 on the base plate 1 to a perimeter of an orthogonal projection of an isolation opening 9 corresponding to the encapsulation portion 801 on the base plate 1 is less than or equal to 45. For example, the ratio may be 40, 35, 30, 25, 20, or 15, etc. By reasonably setting this ratio, the stability of the encapsulation unit 8 may be improved, making the encapsulation unit 8 less likely to fall off. The area of the orthogonal projection of the encapsulation portion 801 on the base plate 1 is an area of an orthogonal projection of the isolation opening 9 defined by the isolation structure 7 on the base plate 1.

Optionally, a gap exists between a side, facing the base plate 1, of the edge encapsulating portion 802, and a side, facing away from the base plate 1, of the isolation structure 7.

The edge encapsulating portion 802 and the encapsulation portion 801 are integrally formed. The orthogonal projection of the encapsulation portion 801 on the base plate 1 covers the orthogonal projection of the light-emitting unit 5 on the base plate 1 corresponding to the encapsulation portion 801. The encapsulation portion 801 is an effective encapsulation portion of the light-emitting unit 5.

Furthermore, the ratio of the area of the orthogonal projection of the encapsulation portion 801 on the base plate 1 to the perimeter of the orthogonal projection of the isolation opening 9 corresponding to the encapsulation portion 801 on the base plate 1 may be less than or equal to 30. For example, the ratio may be 30, 28, 25, 23, 20, 17, or 15, etc. Thus, the stability of the encapsulation unit 8 may be further improved.

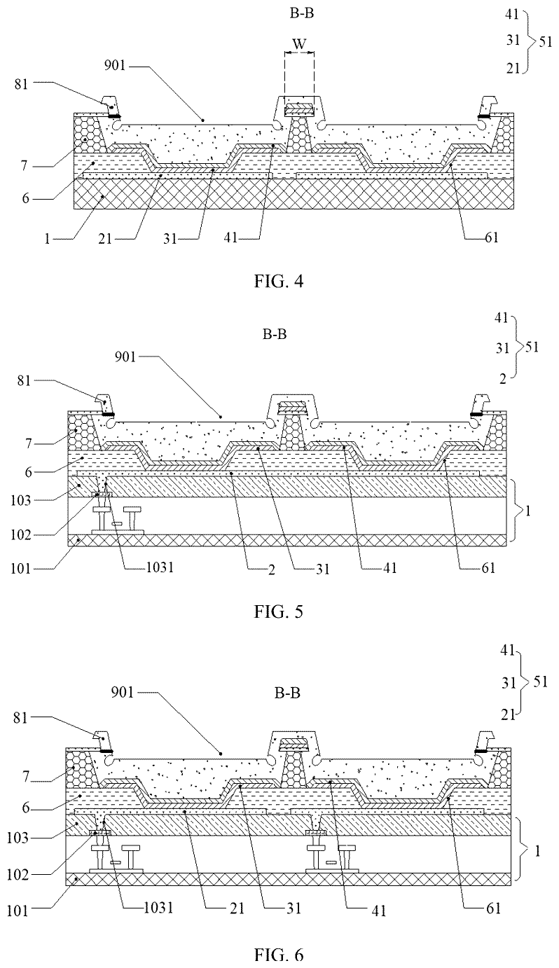

In some possible implementations, referring to FIG. 3 and FIG. 4, the isolation opening 9 may include at least two sub-isolation openings 901. The light-emitting unit 5 may include at least two sub-light-emitting units 51. The sub-light-emitting unit 51 is located in the sub-isolation opening 901. The encapsulation unit 8 covers a plurality of sub-light-emitting units 51 located in a same isolation opening 9, and is in contact with the isolation structure 7 located between two adjacent sub-isolation openings 901.

A same light-emitting unit 5 is divided into at least two sub-light-emitting units 51. Therefore, the sub-light-emitting units 51 located in the same isolation opening 9 emit light of a same color. Adjacent sub-light-emitting units 51 are separated by the isolation structure 7. The encapsulation unit 8 may contact with the isolation structure 7 located between the adjacent sub-light-emitting units 51. Thus, a contact area between the encapsulation unit 8 and the isolation structure 7 may be further increased, resulting in a stronger adhesive force between the encapsulation unit 8 and the isolation structure 7, thereby improving the stability of the encapsulation unit 8, and making the encapsulation unit 8 less likely to fall off.

The encapsulation unit 8 may include a sub-encapsulation portion 8011 located in the sub-isolation opening 901. A ratio of an area of an orthogonal projection of the sub-encapsulation portion 8011 on the base plate 1 to a perimeter of an orthogonal projection of a sub-isolation opening 901 corresponding to the sub-encapsulation portion 8011 on the base plate 1 is less than or equal to 45. For example, the ratio may be 40, 35, 30, 25, 20, or 15, etc. By reasonably setting this ratio, the stability of the encapsulation unit 8 may be improved, making the encapsulation unit 8 less likely to fall off. The area of the orthogonal projection of the sub-encapsulation portion 8011 on the base plate 1 is an area of the orthogonal projection of the sub-isolation opening 901 defined by the isolation structure 7 on the base plate 1.

The ratio of the area of the orthogonal projection of the sub-encapsulation portion 8011 on the base plate 1 to the perimeter of the orthogonal projection of the sub-isolation opening 901 corresponding to the sub-encapsulation portion 8011 on the base plate 1 may be less than or equal to 30. For example, the ratio may be 30, 28, 25, 23, 20, 17, or 15, etc. Thus, the stability of the encapsulation unit 8 may be further improved.

The encapsulation unit 8 covers the isolation structure 7 located between the two adjacent sub-isolation openings 901. The encapsulation unit 8 covers side walls of the isolation structure 7 located between the adjacent sub-isolation openings 901 and a side, facing away from the base plate 1, of the isolation structure 7. Thus, a contact area between the encapsulation unit 8 and the isolation structure 7 may be further increased.

A width W of an orthogonal projection of the isolation structure 7 located between the two adjacent sub-isolation openings 901 on the base plate 1 is greater than or equal to 3 μm, and less than or equal to 6 μm.

For example, the width W may be 3 μm, 3.5 μm, 4 μm, 5 μm, 5.5 μm, or 6 μm, etc. By reasonably setting the width W, the encapsulation effect of the encapsulation unit 8 on the light-emitting unit 5 may be improved without affecting a light-emitting effect of the light-emitting unit 5.

A shape of the orthogonal projection of the sub-isolation opening 901 on the base plate 1 includes at least one of a rectangle and a square. Accordingly, the isolation opening 9 may be divided into sub-isolation openings 901 of different shapes based on actual requirements.

A shape of the orthogonal projection of the sub-isolation opening 901 on the base plate 1 is a rectangle. When the areas of the orthogonal projections of the sub-isolation openings 901 on the base plate 1 are equal, a perimeter of the sub-isolation opening 901 of a rectangle shape may be larger, so that the contact area between the encapsulation unit 8 and the isolation structure 7 is larger, further enhancing the stability of the encapsulation unit 8.

In some possible implementations, referring to FIGS. 2-4 again, the light-emitting unit 5 includes a first electrode 2, a light-emitting portion 3, and a second electrode 4 sequentially stacked in a direction away from the base plate 1. The second electrode 4 is electrically connected to a first isolation portion 71. The display panel further includes a pixel defining layer 6 located between the base plate 1 and the isolation structure 7. A pixel opening 61 is provided on the pixel defining layer 6, and the pixel opening 61 is in communication with the isolation opening 9.

Optionally, the light-emitting portion 3 may include a plurality of sub-light-emitting portions 31 spaced apart. The second electrode 4 includes a plurality of second sub-electrodes 41 spaced apart. The sub-light-emitting unit 31 includes a sub-light-emitting portion 31 and a second sub-electrode 41.

During a manufacturing process of the light-emitting portion 3, the light-emitting portion 3 may be disconnected at the isolation structure 7 located between adjacent sub-isolation openings 901 to form the sub-light-emitting portions 31. During a manufacturing process of the second electrode 4, the second electrode 4 may be disconnected at the isolation structure 7 located between the adjacent sub-isolation openings 901 to form the second sub-electrodes 41. The second sub-electrode 41 overlaps with the isolation structure 7.

Referring to FIGS. 3 to 6, the base plate 1 includes a substrate 101, a conductive layer 102 and an insulating layer 103 sequentially stacked on a side of the substrate 101. A plurality of via holes 1031 extending through the insulating layer 103 are arranged in the insulating layer 103. The first electrode 2 is electrically connected to the conductive layer 103 through a via hole 1031.

The display panel may further include a buffer layer, a semiconductor layer, a first conductive layer, a second conductive layer, a third conductive layer, and a fourth conductive layer sequentially stacked on a side of the substrate 101. Therein, the semiconductor layer includes a source region, a drain region, and a channel region. The first conductive layer includes a gate and a first capacitor plate. The second conductive layer includes a second capacitor plate. A capacitor is formed by the first capacitor plate and the second capacitor plate. The third conductive layer includes a drain and a source. The drain is electrically connected to the drain region, and the source is electrically connected to the source region. A driving transistor is formed by the gate, source, and drain. In the present embodiment, the conductive layer 102 is located in the fourth conductive layer. A side, closer to the substrate 101, of the conductive layer 102 is electrically connected to the drain of the driving transistor. A side, facing away from the substrate 101, of the conductive layer 102 is electrically connected to the first electrode 2 through the via hole 1031. Thus, a signal of the driving transistor may be transmitted to the first electrode 2 through the conductive layer 102 to light up a corresponding light-emitting unit 5.

In some embodiment, referring to FIG. 3 and FIG. 5, a plurality of sub-light-emitting units 51 located within the same isolation opening 9 share a same first electrode 2. In the present embodiment, the plurality of sub-light-emitting units 51 within the same isolation opening 9 are powered by the same first electrode 2. A sub-light-emitting unit 51 includes a first electrode 2, a sub-light-emitting portion 31, and a second sub-electrode 41.

In some other embodiments, referring to FIG. 3 and FIG. 6 again, the first electrode 2 includes a plurality of first sub-electrodes spaced apart, and a sub-light-emitting unit includes a first sub-electrode. The first sub-electrode 21 is electrically connected to the conductive layer 102 through the via hole 1031.

In the present embodiments, for example, the isolation opening 9 may be divided into two sub-isolation openings 901, and the first electrode 2 may be divided into two first sub-electrodes 21. A sub-isolation opening 901 is provided with a sub-light-emitting unit 51, and the sub-light-emitting unit 51 includes a first sub-electrode 21, a sub-light-emitting portion 31, and a second sub-electrode 41. The first sub-electrode 21 of each sub-light-emitting unit 51 is electrically connected to the conductive layer 102 through a via hole 1031. Thus, the first sub-electrodes 21 of different sub-light-emitting units 51 within the same isolation opening 9 are independent of each other. When the first sub-electrode 21 of one sub-light-emitting unit 51 is damaged (e.g., by oxidation), it will not affect first sub-electrodes 21 of other sub-light-emitting units 51, and therefore will not affect the normal display of the other sub-light-emitting units 51, thereby improving the display effect of the display panel.

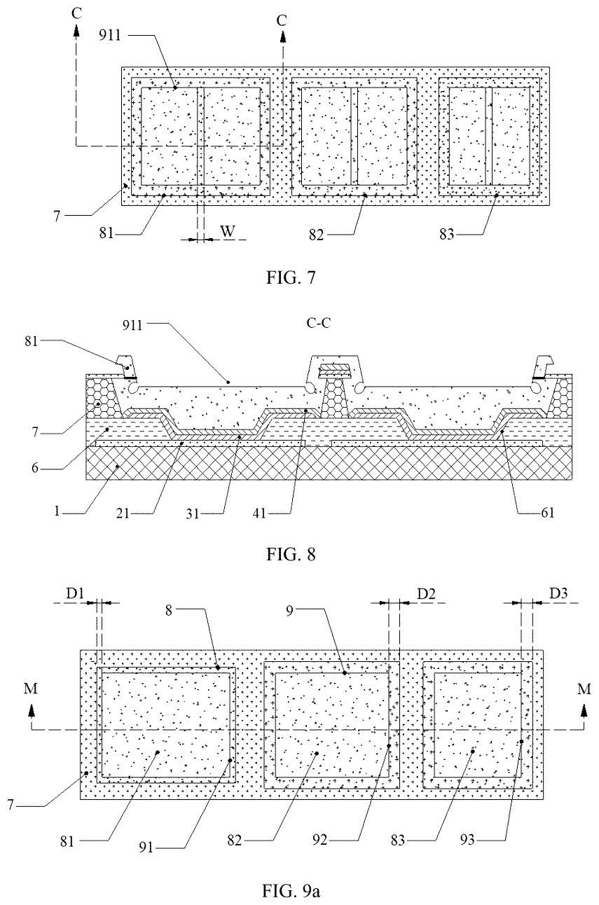

Referring to FIG. 7 and FIG. 8, the first isolation opening 91 may include at least two first sub-isolation openings 911, the first light-emitting unit may include at least two first sub-light-emitting units 51. A first sub-light-emitting unit 51 is located in a first sub-isolation opening 911.

Based on analysis mentioned above, in the related art, the first encapsulation unit 81 is less stable compared with the second encapsulation unit 82 and the third encapsulation unit 83. Therefore, in the present embodiment, only the first isolation opening 91 may be divided into a plurality of first sub-isolation openings 911. Thus, a contact area between the first encapsulation unit 81 and the isolation structure 7 may be increased, thereby enhancing the stability of the first encapsulation unit 81.

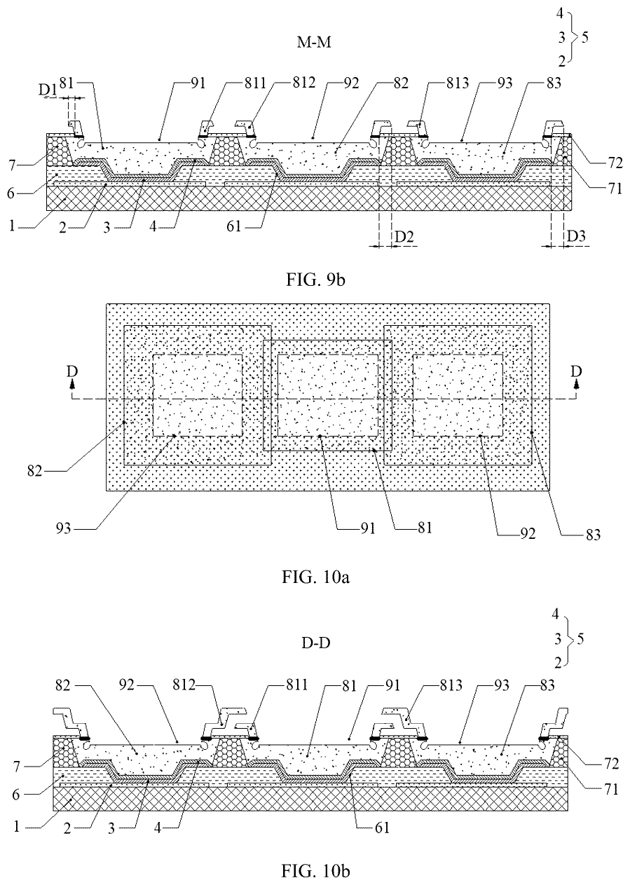

In some possible implementations, referring to FIG. 9a and FIG. 9b, the first encapsulation unit 81 may include a first edge encapsulating portion 811 located on a side, facing away from the base plate 1, of the isolation structure 7. The second encapsulation unit 82 may include a second edge encapsulating portion 812 located on the side, facing away from the base plate 1, of the isolation structure 7. Along the arrangement direction of the first isolation opening 91 and the second isolation opening 92, an extension length D1 of the first edge encapsulating portion 811 is less than an extension length D2 of the second edge encapsulating portion 812.

Optionally, the third encapsulation unit 83 includes a third edge encapsulating portion 813 located on the side, facing away from the base plate 1, of the isolation structure 7. Along an arrangement direction of the first isolation opening 91 and the third isolation opening 93, an extension length D1 of the first edge encapsulating portion 811 is less than an extension length D3 of the third edge encapsulating portion 813.

A gap is provided between a side, facing the base plate 1, of the first edge encapsulating portion 811, and a side, facing away from the base plate 1, of the isolation structure 7. A gap is provided between a side, facing the base plate 1, of the second edge encapsulating portion 812, and a side, facing away from the base plate 1, of the isolation structure 7. A gap is provided between a side, facing the base plate 1, of the third edge encapsulating portion 813, and a side, facing away from the base plate 1, of the isolation structure 7. It can be seen that the first edge encapsulating portion 811, the second edge encapsulating portion 812, and the third edge encapsulating portion 813 are in a suspended state.

Since the edge encapsulating portion 802 is in the suspended state, the extension length of the edge encapsulating portion 802 may affect the stability of the encapsulation unit 8. Specifically, a longer extension length of the edge encapsulating portion 802 may lead to greater scouring force that a corresponding encapsulation unit 8 may experience, and greater possibility for the corresponding encapsulation unit 8 to fall off.

In the present embodiment, the extension length D1 of the first edge encapsulating portion 811 is set to be less than the extension length D2 of the second edge encapsulating portion 812, and the extension length D1 of the first edge encapsulating portion 811 is also set to be less than the extension length D3 of the third edge encapsulating portion 813. Thus, the first encapsulation unit 81 is more stable compared with the second encapsulation unit 82 and the third encapsulation unit 83. In a condition where the second encapsulation unit 82 and the third encapsulation unit 83 are not prone to falling off, the first encapsulation unit 81 will not be likely to fall off.

Along the arrangement direction of the first isolation opening 91 and the second isolation opening 92, the extension length D1 of the first edge encapsulating portion 811 may be greater than or equal to 1 μm and less than or equal to 6 μm.

For example, the extension length D1 may be 1 μm, 2 μm, 3 μm, 4 μm, 5 μm, or 6 μm, etc. By reasonably setting of the extension length D1, the stability of the first encapsulation unit 81 may be improved.

Referring to FIG. 10a and FIG. 10b, the first edge encapsulating portion 811 at least partially overlaps with the second edge encapsulating portion 812, and the first edge encapsulating portion 811 is located on a side, facing the base plate 1, of the second edge encapsulating portion 812.

Optionally, the first edge encapsulating portion 811 at least partially overlaps with the third edge encapsulating portion 813, and the first edge encapsulating portion 811 is located on a side, facing the base plate 1, of the third edge encapsulating portion 813.

The first edge encapsulating portion 811 overlaps with both the second edge encapsulating portion 812 and the third edge encapsulating portion 813, and the first edge encapsulating portion 811 is located on the side, facing the base plate 1, of both the second edge encapsulating portion 812 and the third edge encapsulating portion 813. Thus, when the external scouring force impacts the encapsulation unit 8, the scouring force first impacts the second edge encapsulating portion 812 and the third edge encapsulating portion 813. The second edge encapsulating portion 812 and the third edge encapsulating portion 813 may protect the first edge encapsulating portion 811, making it less likely to break, thereby reducing the scouring force experienced by the first encapsulation unit 81, and further reducing risk for the first encapsulation unit 81 to fall off.

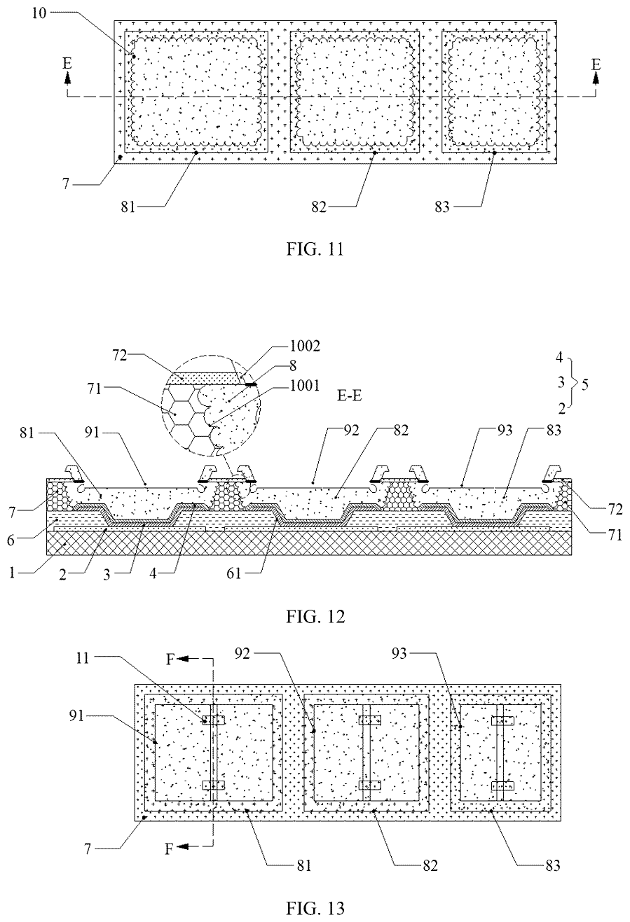

In some possible implementations, referring to FIGS. 11 to 12, a concave-convex structure 10 is arranged on a side wall, facing the isolation opening 9, of the isolation structure 7. The encapsulation unit 8 is in contact with the concave-convex structure 10.

The concave-convex structure 10 is provided on the side wall, facing the isolation opening 9, of the isolation structure 7, thereby increasing a surface area of the side wall of the isolation structure 7. As the encapsulation unit 8 is in contact with the side wall of the isolation structure 7, a contact area between the encapsulation unit 8 and the isolation structure 7 may be increased, thereby enhancing the adhesion between the encapsulation unit 8 and the isolation structure 7, and further improving the stability of the encapsulation unit 8 and making the encapsulation unit 8 less likely to fall off.

The concave-convex structure 10 may include a first concave-convex structure 1001, and the first concave-convex structure 1001 is located on a side, facing the isolation opening 9, of a first isolation portion 71.

Optionally, the concave-convex structure 10 may include a second concave-convex structure 1002, and the second concave-convex structure 1002 is located on a side, facing the isolation opening 9, of a second isolation portion 72.

The encapsulation unit 8 is in contact with both the first concave-convex structure 1001 and the second concave-convex structure 1002. Thus, the concave-convex structure 10 covers an entire side wall, facing the isolation opening 9, of the isolation structure 7, thereby further increasing the contact area between the encapsulation unit 8 and the isolation structure 7.

The first concave-convex structure is serrated. Compared with other shapes of the concave-convex structures 10, the serrated first concave-convex structure 1001 may further increase a surface area of a side wall, facing the isolation opening 9, of the first isolation portion 71, thereby further increasing the contact area between the encapsulation unit 8 and the isolation structure 7.

The encapsulation unit 8 may be mutually embedded with the concave-convex structure 10. The encapsulation unit 8 and the concave-convex structure 10 are tightly interlocked with each other, thereby increasing the adhesion between the encapsulation unit 8 and the concave-convex structure 10.

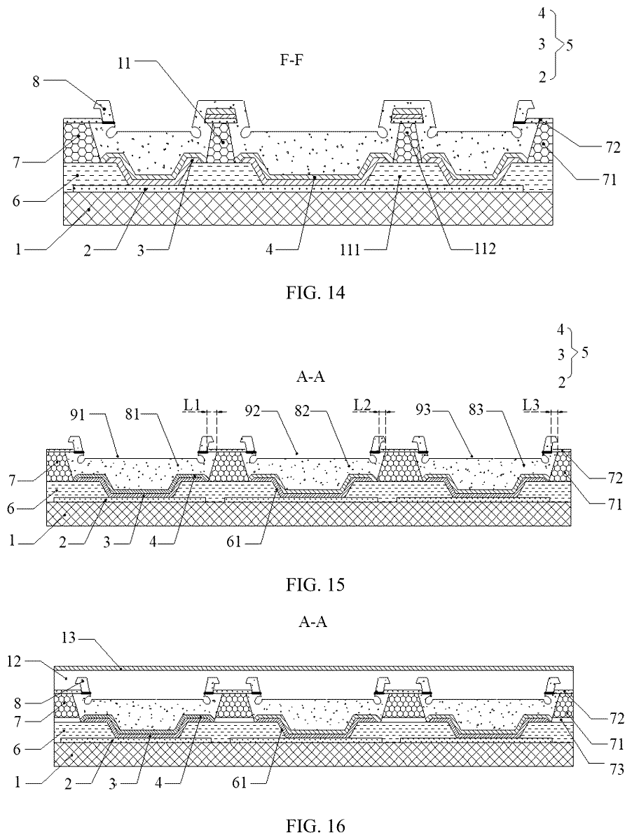

In some possible implementations, referring to FIGS. 13 and 14, the display panel may further include a reinforcement block 11 located in the isolation opening 9, and the encapsulation unit 8 is in contact with the reinforcement block 11.

An orthogonal projection of the reinforcement block 11 on the base plate 1 is located outside an orthogonal projection of the isolation structure 7 on the base plate 1. The orthogonal projection of the reinforcement block 11 on the base plate 1 is located outside an orthogonal projection of the pixel defining layer 6 on the base plate 1. That is, the reinforcement block 11 is not in contact with the isolation structure 7 and the pixel defining layer 6, and is independently provided in the isolation opening 9, so as not to affect the normal display of the light-emitting unit 5.

Since the encapsulation unit 8 is in contact with the reinforcement block 11, a contact area between the encapsulation unit 8 and the reinforcement block 11 may be increased, thereby enhancing the stability of the encapsulation unit 8.

The encapsulation unit 8 may extend from a side wall, facing the isolation structure 7, of the reinforcement block 11, to a side, facing away from the base plate 1, of the reinforcement block 11 to cover the reinforcement block 11. As the encapsulation unit 8 covers an exposed surface of the reinforcement block 11, the contact area between the encapsulation unit 8 and the reinforcement block 11 may be further increased.

A quantity of the reinforcement blocks 11 may be greater than one. Thus, without affecting the normal display of the light-emitting unit 5, the contact area between the encapsulation unit 8 and the reinforcement block 11 may be further increased.

In some possible implementations, along a direction away from the base plate 1, the reinforcement block 11 may include a first reinforcement portion 111 and a second reinforcement portion 112, and the second reinforcement portion 112 is in a same layer as the isolation structure 7. The second reinforcement portion 112 has a same structure of layers as the isolation structure 7, and a material of the second reinforcement portion 112 is the same as the isolation structure 7.

Optionally, the first reinforcement portion 111 is in a same layer as the pixel defining layer 6, and a material of the first reinforcement portion 111 is the same as the pixel defining layer 6.

The first reinforcement portion 111 may be formed simultaneously with the pixel defining layer 6, and the second reinforcement portion 112 may be formed simultaneously with the isolation structure 7. Therefore, there is no need to set up a dedicated process for forming the first reinforcement portion 111 and the second reinforcement portion 112, thereby reducing process cost of the reinforcement block 11.

In some possible implementations, referring to FIG. 1 and FIG. 15, a minimum distance between an edge of an orthogonal projection of a side, facing away from the base plate 1, of the first isolation portion 71 corresponding to the first light-emitting unit on the base plate and an edge of an orthogonal projection of a side, facing the base plate 1, of second isolation portion 72 on the base plate is a first distance L1; and a minimum distance between an edge of an orthogonal projection of a side, facing away from the base plate 1, of the first isolation portion 71 corresponding to the second light-emitting unit on the base plate and an edge of an orthogonal projection of a side, closer to the base plate 1, of the second isolation portion 72 on the base plate 1 is a second distance L2. The first distance L1 is greater than the second distance L2.

A minimum distance between an edge of an orthogonal projection of a side, facing away from the base plate 1, of the first isolation portion 71 corresponding to the third light-emitting unit on the base plate and an edge of an orthogonal projection of a side, closer to the base plate 1, of the second isolation portion 72 on the base plate 1 is a third distance L3. The first distance L1 is greater than the third distance L3.

The larger the minimum distance between the edge of the orthogonal projection of the side, facing away from the base plate 1, of the first isolation portion 71 on the base plate, and the edge of the orthogonal projection of the side, closer to the base plate 1, of the second isolation portion 72 on the base plate 1 is, the greater an etching amount for the first isolation portion 71 is, and the longer a length of the second isolation portion 72 extending outside the first isolation portion 71 is, leading to a larger contact area between the encapsulation unit 8 and both the first isolation portion 71 and the second isolation portion 72.

In the present embodiment, the first distance L1 is set to be greater than the second distance L2, and the first distance L1 is set to be greater than the third distance L3. As a result, a contact area between the first encapsulation unit 81 and the isolation structure 7 is relatively larger than a contact area between the second encapsulation unit 82 and the isolation structure, as well as a contact area between the third encapsulation unit 83 and the isolation structure 7. Given that the first encapsulation unit 81 and the second encapsulation unit 82 are not prone to falling off, the third encapsulation unit 83 is also less likely to fall off, thereby enhancing an encapsulation effect of the encapsulation unit 8 on the light-emitting unit 5.

The first distance L1 may be greater than or equal to 0.3 μm and less than or equal to 0.7 μm. For example, the first distance L1 may be 0.3 μm, 0.4 μm, 0.5 μm, 0.6 μm, or 0.7 μm, etc. By reasonably setting the first distance L1, while ensuring effective overlapping between the second electrode 4 of the first light-emitting unit and the isolation structure 7, an area of an overlapping region between the first encapsulation unit 81 and the isolation structure 7 may be increased.

In some possible implementations, referring to FIG. 1 and FIG. 2 again, the isolation structure 7 may include a first isolation portion 71 and a second isolation portion 72 sequentially stacked along a direction away from the base plate 1. A second electrode 4 of the light-emitting unit 5 is electrically connected to the first isolation portion 71. An orthogonal projection of a side, facing away from the base plate 1, of the first isolation portion 71 on the base plate 1, is located within an orthogonal projection of the second isolation portion 72 on the base plate 1.

Since the second isolation portion 72 is located on a side, facing away from the base plate 1, of the first isolation portion 71, and in a plane parallel to the base plate 1, a horizontal width of the second isolation portion 72 is greater than a horizontal width of the first isolation portion 71. Therefore, a light-emitting material layer and a second electrode material layer may be disconnected by the second isolation portion 72 at the isolation structure 7. Thus, the isolation structure 7 formed by the first isolation portion 71 and the second isolation portion 72 may more easily enable independent encapsulation of each light-emitting unit, thereby improving the encapsulation yield of the display panel.

A first opening 16 is defined by the side, facing away from the base plate 1, of the first isolation portion 71. The first opening 16 may include a first sub-opening 161, a second sub-opening 162 and a third sub-opening 163. An area of an orthogonal projection of the first sub-opening 161 on the base plate 1 is larger than an area of an orthogonal projection of the second sub-opening 162 on the base plate 1. The area of the orthogonal projection of the first sub-opening 161 on the base plate 1 is larger than an area of an orthogonal projection of the third sub-opening 163 on the base plate 1. At least part of the first light-emitting unit is located in the first sub-opening 161, at least part of the second light-emitting unit is located in the second sub-opening 162, and at least part of the third light-emitting unit is located in the third sub-opening 163.

A ratio of an area of an orthogonal projection of the first encapsulation unit 81 on the base plate 1 to a perimeter of an orthogonal projection of the first sub-opening 161 on the base plate 1 is a tenth ratio, a ratio of an area of an orthogonal projection of the second encapsulation unit 82 on the base plate 1 to a perimeter of an orthogonal projection of the second sub-opening 162 on the base plate 1 is a eleventh ratio, a ratio of an area of an orthogonal projection of the third encapsulation unit 83 on the base plate to a perimeter of an orthogonal projection of the third sub-opening 163 on the base plate is a twelfth ratio, the tenth ratio is less than or equal to a sum of the eleventh ratio and the twelfth ratio. Thus, the stability of the first encapsulation unit 81, the second encapsulation unit 82, and the third encapsulation unit 83 may be further improved.

Referring to FIG. 16, the isolation structure 7 may further include a third isolation portion 73 located on a side, facing the base plate 1, of the first isolation portion 71. The second electrode 4 of the light-emitting unit 5 is electrically connected to the third isolation portion 73.

A material of the third isolation portion 73 may include a conductive material. The second electrode 4 corresponding to the light-emitting unit 5 extends to contact a side wall of the third isolation portion 73 to achieve electrical connection between the second electrode 4 corresponding to the light-emitting unit 5 and the third isolation portion 73.

Specifically, a material of the third isolation portion includes Mo; and/or a material of the first isolation portion includes Al; and/or a material of the second isolation portion includes Ti. Thus, when the second electrode 4 material layer are disconnected by the isolation structure 7 into the second electrodes 4, the second electrode 4 is more easily electrically connected to the first isolation portion 71 and/or the third isolation portion 73.

An orthogonal projection of the light-emitting portion 3 on the base plate 1 is located outside an orthogonal projection of the third isolation portion 73 and/or the first isolation portion 71 on the base plate 1. Thus, the light-emitting portion 3 does not overlap with the isolation structure 7, thereby effectively improving a crosstalk problem between light-emitting units 5.

The orthogonal projection of the isolation opening 9 on the base plate 1 in all the embodiments mentioned above may be a rectangular shape and/or a rectangle-like shape.

Furthermore, the rectangular shape includes at least one of a rectangle and a square, and the rectangle-like includes at least one of a rectangle with chamfered corners or a rectangle with rounded corners.

Specifically, in an embodiment, referring to FIG. 1 again, the orthogonal projection of the isolation opening 9 on the base plate 1 is a rectangle.

In another embodiment, referring to FIG. 17, the orthogonal projection of the isolation opening 9 on the base plate 1 is a square.

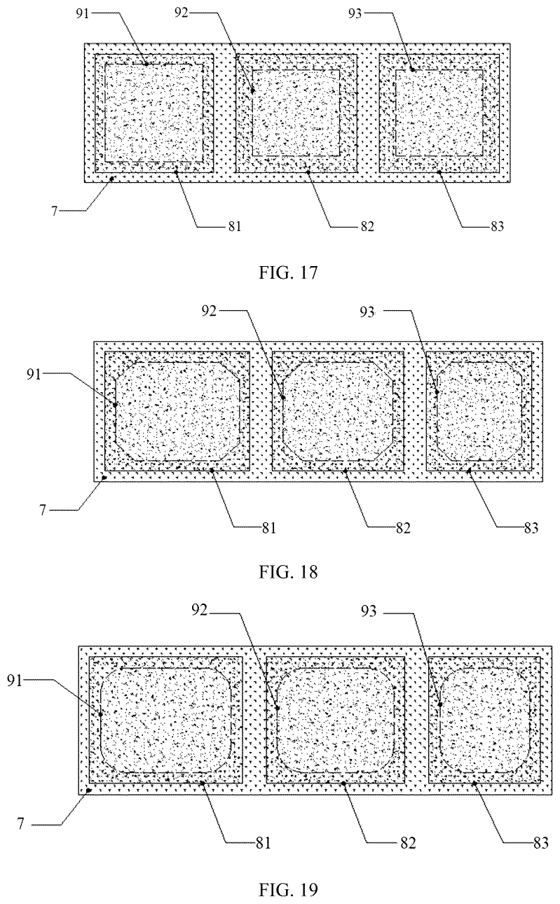

In still another embodiment, referring to FIG. 18, the orthogonal projection of the isolation opening 9 on the base plate 1 is a rectangle with chamfered corners.

In yet still another embodiment, referring to FIG. 19, the orthogonal projection of the isolation opening 9 on the base plate 1 is a rectangle with rounded corners.

Thus, the isolation opening 9 may be configured to be of different shapes according to actual requirements.

Furthermore, the orthogonal projection of the isolation opening 9 on the base plate 1 may be a rectangle. When areas of orthogonal projections of the isolation openings 9 on the base plate 1 are equal, an isolation opening 9 in the shape of the rectangle has a larger perimeter. Therefore, the contact area between the encapsulation unit 8 and the isolation structure 7 is larger, further enhancing the stability of the encapsulation unit 8.

Referring to FIG. 16 again, the display panel may further include a second encapsulation layer 12 located on a side, facing away from the base plate 1, of a first encapsulation layer, and a third encapsulation layer 13 located on a side, facing away from the base plate 1, of the second encapsulation layer 12.

Both a material of the first encapsulation layer and a material of the third encapsulation layer 13 include an inorganic material.

A material of the second encapsulation layer 12 includes an organic material.

For example, the first encapsulation layer and the third encapsulation layer 13 may be formed by Chemical Vapor Deposition (CVD), and the second encapsulation layer 12 may be formed by Ink-Jet Printing (IJP). The second encapsulation layer 12 and the third encapsulation layer 13 may provide better encapsulation for the light-emitting unit 5, thereby further improving the encapsulation quality of the display panel.

In some possible implementations, referring to FIG. 1 and FIG. 2 again, the present disclosure further provides a display panel. The display panel includes a base plate 1, an isolation structure 7, a plurality of light-emitting units 5, and a plurality of encapsulation units 8.

The isolation structure 7 is located on a side of the base plate 1. The isolation structure 7 includes a first isolation portion 71 and a second isolation portion 72 sequentially stacked along a direction away from the base plate 1. A plurality of isolation openings 9 are defined by the second isolation portion 72. The plurality of isolation openings 9 include a first isolation opening 91, a second isolation opening 92, and a third isolation opening 93. An area of an orthogonal projection of the first isolation opening 91 on the base plate 1 is larger than an area of an orthogonal projection of the second isolation opening 92 on the base plate 1, and the area of the orthogonal projection of the first isolation opening 91 on the base plate 1 is larger than an area of an orthogonal projection of the third isolation opening 93 on the base plate 1.

The plurality of light-emitting units 5 include a first light-emitting unit, a second light-emitting unit, and a third light-emitting unit. At least part of the first light-emitting unit is located in the first isolation opening 91, at least part of the second light-emitting unit is located in the second isolation opening 92, and at least part of the third light-emitting unit is located in the third isolation opening 93.

The plurality of encapsulation units 8 include a first encapsulation unit 81, a second encapsulation unit 82, and a third encapsulation unit 83. The first encapsulation unit 81 is located on a side, facing away from the base plate 1, of the first light-emitting unit, the second encapsulation unit 82 is located on a side, facing away from the base plate 1, of the second light-emitting unit, and the third encapsulation unit 83 is located on a side, facing away from the base plate 1, of the third light-emitting unit.

Therein, a ratio of an area of the first encapsulation unit 81 to an area of an overlapping region between the first encapsulation unit 81 and the isolation structure 7 is a fourth ratio; a ratio of an area of the second encapsulation unit 82 to an area of an overlapping region between the second encapsulation unit 82 and the isolation structure 7 is a fifth ratio; and a ratio of an area of the third encapsulation unit 83 to an area of an overlapping region between the third encapsulation unit 83 and the isolation structure 7 is a sixth ratio. The fourth ratio is less than or equal to a sum of the fifth ratio and the sixth ratio.

Light emitted by the first light-emitting unit, the second light-emitting unit, and the third light-emitting unit is different from each other in color. For example, a color of light emitted by the first light-emitting unit includes red, a color of light emitted by the second light-emitting unit includes green, and a color of light emitted by the third light-emitting unit includes blue. Generally, the area of the orthogonal projection of the first isolation opening 91 corresponding to the first light-emitting unit on the base plate 1 is larger than both the area of the orthogonal projection of the second isolation opening 92 corresponding to the second light-emitting unit on the base plate 1 and the area of the orthogonal projection of the third isolation opening 93 corresponding to the third light-emitting unit on the base plate 1.

The larger an area of the isolation opening 9 is, the larger an area of the encapsulation unit 8 covering the isolation opening 9 is. Therefore, generally, the area of the first encapsulation unit 81 is greater than both the area of the second encapsulation unit 82 and the area of the third encapsulation unit 83.

In the present embodiment, the area of the encapsulation unit 8 refers to an area of a side, facing away from the base plate 1, of the encapsulation unit 8. The area of the overlap region between the encapsulation unit 8 and the isolation structure 7 mainly refers to an area of a part that the encapsulation unit 8 contacts with the isolation structure 7. A larger area for the encapsulation unit 8 leads to greater external scouring forces and a higher probability of detachment. Therefore, the first encapsulation unit 81 typically experiences greater external scouring force than the second encapsulation unit 82 and the third encapsulation unit 83, and the first encapsulation unit 81 is relatively more likely to fall off compared with the second encapsulation unit 82 and the third encapsulation unit 83.

In addition, a larger contact area between the encapsulation unit 8 and the isolation structure 7 leads to stronger adhesive force between the encapsulation unit 8 and the isolation structure 7, better stability of the encapsulation unit 8, and less possibility for the encapsulation unit 8 to fall off.

In view of above, stability of the encapsulation unit 8 is related to the contact area between the encapsulation unit 8 and the isolation structure 7, as well as the area of the encapsulation unit 8.

After a long-term research, the inventors found that in the display panel, stability of the second encapsulation unit 82 and the third encapsulation unit 83 is relatively better than stability of the first encapsulation unit 81, and the second encapsulation unit 82 and the third encapsulation unit 83 are less likely to fall off under the external force. Therefore, based on the second encapsulation unit 82 and the third encapsulation unit 83, when the ratio of the area of the first encapsulation unit 81 to the area of the overlapping region between the first encapsulation unit 81 and the isolation structure 7 is less than or equal to a sum of the ratio of the area of the second encapsulation unit 82 to the area of the overlapping region between the second encapsulation unit 82 and the isolation structure 7 and the ratio of the area of the third encapsulation unit 83 to the area of the overlapping region between the third encapsulation unit 83 and the isolation structure 7, that is, when the fourth ratio is less than or equal to a sum of the fifth ratio and the sixth ratio, the stability of the first encapsulation unit 81 may be ensured, thereby enabling the first encapsulation unit 81 to provide better encapsulation effect for the first light-emitting unit. As a result, the first light-emitting unit is less likely to develop dark spots, thereby improving a display effect of the display panel.

In some possible implementations, the fourth ratio is greater than the fifth ratio, and the fourth ratio is greater than the sixth ratio.

The fourth ratio may be less than or equal to 50, the fifth ratio may be less than or equal to 50, and the sixth ratio may be less than or equal to 50. For example, the fourth ratio, the fifth ratio, and the sixth ratio may be 50, 45, 40, 35, 30, 25, 20, or 15, etc. Thus, the stability of the encapsulation unit 8 may be improved, making the encapsulation unit 8 less likely to fall off.

Furthermore, the fourth ratio may be less than or equal to 35, the fifth ratio may be less than or equal to 35, and the sixth ratio may be less than or equal to 35. For example, the fourth ratio, the fifth ratio, and the sixth ratio may be 35, 30, 25, 20, or 15, etc. Thus, the stability of the encapsulation unit 8 may be improved, making the encapsulation unit 8 less likely to fall off.

A ratio of an area of an orthogonal projection of the first encapsulation unit 81 on the base plate 1 to the area of the overlapping region between the first encapsulation unit 81 and the isolation structure 7 is a seventh ratio, a ratio of an area of an orthogonal projection of the second encapsulation unit 82 on the base plate 1 to the area of the overlapping region between the second encapsulation unit 82 and the isolation structure 7 is a eighth ratio, and a ratio of an area of an orthogonal projection of the third encapsulation unit 83 on the base plate 1 to the area of the overlapping region between the third encapsulation unit 83 and the isolation structure 7 is a ninth ratio. The seventh ratio is less than or equal to a sum of the eighth ratio and the ninth ratio.

Based on analysis mentioned above, the stability of the encapsulation unit 8 is related to the contact area between the encapsulation unit 8 and the isolation structure 7, as well as the area of the orthogonal projection of the encapsulation unit 8 on the base plate 1. when the seventh ratio is less than or equal to the sum of the eighth ratio and the ninth ratio, the stability of the first encapsulation unit 81 may be improved, thereby ensuring that the first encapsulation unit 81 is less likely to fall off, enabling the first encapsulation unit 81 to provide better encapsulation for the first light-emitting unit. As a result, the first light-emitting unit is less likely to develop dark spots, thereby improving a display effect of the display panel.

The seventh ratio may be greater than the eighth ratio, and the seventh ratio may be greater than the ninth ratio.

Other technical solutions of the display panel in the present embodiment are the same as the technical solutions of the display panel in the above embodiments, which will be repeated herein again.

In some possible implementations, referring to FIG. 1 and FIG. 2, the present disclosure further provides a display panel. The display panel includes a base plate 1, an isolation structure 7, a plurality of light-emitting units 5, and a plurality of encapsulation units 8.

The isolation structure 7 is located on a side of the base plate 1. The isolation structure 7 includes a first isolation portion 71 and a second isolation portion 72 sequentially stacked along a direction away from the base plate 1. A plurality of isolation openings 9 are defined by the second isolation portion 72.

At least part of a light-emitting unit 5 is located in an isolation opening 9. An encapsulation unit 8 is located on a side, facing away from the base plate 1, of the light-emitting unit 5.

A ratio of an area of an orthogonal projection of the encapsulation unit 8 on the base plate 1 to a perimeter of an orthogonal projection of an isolation opening 9 corresponding to the encapsulation unit 8 on the base plate 1 is less than or equal to 50. The orthogonal projection of the isolation opening 9 on the base plate 1 is an opening formed by an orthogonal projection of the isolation structure 7 corresponding to the isolation opening 9 on the base plate 1.

Light emitted by the first light-emitting unit, the second light-emitting unit, and the third light-emitting unit is different from each other in color. For example, a color of light emitted by the first light-emitting unit includes red, a color of light emitted by the second light-emitting unit includes green, and a color of light emitted by the third light-emitting unit includes blue. Generally, the area of the orthogonal projection of the first isolation opening 91 corresponding to the first light-emitting unit on the base plate 1 is larger than both the area of the orthogonal projection of the second isolation opening 92 corresponding to the second light-emitting unit on the base plate 1 and the area of the orthogonal projection of the third isolation opening 93 corresponding to the third light-emitting unit on the base plate 1.

The larger an area of the isolation opening 9 is, the larger an area of the encapsulation unit 8 covering the isolation opening 9 is. Therefore, generally, the area of the orthogonal projection of the first encapsulation unit 81 on the base plate 1 is greater than both the area of the orthogonal projection of the second encapsulation unit 82 and the area of the orthogonal projection of the third encapsulation unit 83 on the base plate 1.

A larger area for the encapsulation unit 8 leads to greater external scouring forces and a higher probability of detachment. Therefore, the first encapsulation unit 81 typically experiences greater external scouring force than the second encapsulation unit 82 and the third encapsulation unit 83, and the first encapsulation unit 81 is relatively more likely to fall off compared with the second encapsulation unit 82 and the third encapsulation unit 83.

In addition, a larger perimeter for the orthogonal projection of the isolation opening 9 on the base plate 1 leads to a greater contact area between the encapsulation unit 8 and the isolation structure 7, stronger adhesive force between the encapsulation unit 8 and the isolation structure 7, and less possibility for the encapsulation unit 8 to fall off.

In view of above, stability of the encapsulation unit 8 is related to the perimeter of the orthogonal projection of the isolation opening 9 on the base plate 1, as well as the area of the orthogonal projection of the encapsulation unit 8 on the base plate 1.

After a long-term research, the inventors found that when the ratio of the area of the orthogonal projection of the encapsulation unit 8 on the base plate 1 to the perimeter of the orthogonal projection of the isolation opening 9 corresponding to the encapsulation unit 8 on the base plate 1 is less than or equal to 50 (e.g. the ratio may be 50, 45, 40, 35, 30, 25, 20, or 15, etc.) , the encapsulation unit 8 is less likely to fall off, thereby improving the encapsulation effect of the first encapsulation unit 81 on the first light-emitting unit, and further enhancing the display effect of the display panel.

In some possible implementations, the ratio of the area of the orthogonal projection of the encapsulation unit 8 on the base plate 1 to the perimeter of the orthogonal projection of the corresponding isolation opening 9 of the encapsulation unit 8 on the base plate 1 may be less than or equal to 35. For example, the ratio may be 35, 30, 25, 20, or 15, etc. Thus, the stability of the encapsulation unit 8 may further be improved.

At least part of the encapsulation unit 8 extends from a side, facing the isolation opening 9, of the isolation structure 7, to a side, facing away from the base plate 1, of the isolation structure 7. The encapsulation unit 8 includes an edge encapsulating portion 802 and an encapsulation portion 801 connected to each other. The edge encapsulating portion 802 is located on a side, facing away from the base plate 1, of the isolation structure 7. The encapsulation portion 801 is located in the isolation opening 9. A ratio of an area of an orthogonal projection of the encapsulation portion 801 on the base plate 1 to a perimeter of an orthogonal projection of an isolation opening 9 corresponding to the encapsulation portion 801 on the base plate 1 is less than or equal to 45. For example, the ratio may be 40, 35, 30, 25, 20, or 15, etc. By reasonably setting this ratio, the stability of the encapsulation unit 8 may be improved, making the encapsulation unit 8 less likely to fall off.

The edge encapsulating portion 802 and the encapsulation portion 801 are integrally formed. The orthogonal projection of the encapsulation portion 801 on the base plate 1 covers the orthogonal projection of the light-emitting unit 5 on the base plate 1 corresponding to the encapsulation portion 801. The encapsulation portion 801 is an effective encapsulation portion of the light-emitting unit 5.

The ratio of the area of the orthogonal projection of the encapsulation portion 801 on the base plate 1 to the perimeter of the orthogonal projection of the isolation opening 9 corresponding to the encapsulation portion 801 on the base plate 1 may be less than or equal to 30. For example, the ratio may be 30, 28, 25, 23, 20, 17, or 15, etc. Thus, the stability of the encapsulation unit 8 may be further improved. The area of the orthogonal projection of the encapsulation portion 801 on the base plate 1 refers to an area of an orthogonal projection of the isolation opening 9 defined by the isolation structure 7 on the base plate 1.

Other technical solutions of the display panel in the present embodiment are the same as the technical solutions of the display panel in the above embodiments, which will be repeated herein again.

In some possible implementations, referring to FIG. 1 and FIG. 2, the present disclosure further provides a display panel. The display panel includes a base plate 1, an isolation structure 7, light-emitting units 5, and an encapsulation unit 8.

The isolation structure 7 is located on a side of the base plate 1. The isolation structure 7 includes a first isolation portion 71 and a second isolation portion 72 sequentially stacked along a direction away from the base plate 1. A plurality of isolation openings 9 are defined by the second isolation portion 72.

At least part of the light-emitting unit 5 is located in the isolation opening 9. The encapsulation unit 8 is located on a side, facing away from the base plate 1, of the light-emitting unit 5.

A ratio of an area of the encapsulation unit 8 to an area of an overlapping region between the encapsulation unit 8 and the isolation structure 7 is less than or equal to 50.

The light-emitting units 5 include a first light-emitting unit, a second light-emitting unit, and a third light-emitting unit. Light emitted by the first light-emitting unit, the second light-emitting unit, and the third light-emitting unit is different from each other in color. For example, a color of light emitted by the first light-emitting unit includes red, a color of light emitted by the second light-emitting unit includes green, and a color of light emitted by the third light-emitting unit includes blue. Generally, the area of the orthogonal projection of the first isolation opening 91 corresponding to the first light-emitting unit on the base plate 1 is larger than both the area of the orthogonal projection of the second isolation opening 92 corresponding to the second light-emitting unit on the base plate 1 and the area of the orthogonal projection of the third isolation opening 93 corresponding to the third light-emitting unit on the base plate 1.

The larger an area of the isolation opening 9 is, the larger an area of the encapsulation unit 8 covering the isolation opening 9 is. Therefore, generally, the area of the orthogonal projection of the first encapsulation unit 81 on the base plate 1 is greater than both the area of the orthogonal projection of the second encapsulation unit 82 and the area of the orthogonal projection of the third encapsulation unit 83 on the base plate 1.

A larger area for the encapsulation unit 8 leads to greater external scouring forces and a higher probability of detachment. Therefore, the first encapsulation unit 81 typically experiences greater external scouring force than the second encapsulation unit 82 and the third encapsulation unit 83, and the first encapsulation unit 81 is relatively more likely to fall off compared with the second encapsulation unit 82 and the third encapsulation unit 83.

In addition, a greater contact area between the encapsulation unit 8 and the isolation structure 7 leads to stronger adhesive force between the encapsulation unit 8 and the isolation structure 7, and less possibility for the encapsulation unit 8 to fall off.

In view of above, stability of the encapsulation unit 8 is related to the contact area between the encapsulation unit 8 and the isolation structure 7, as well as the area of the encapsulation unit 8.

After a long-term research, the inventors found that when the ratio of the area of the encapsulation unit 8 to the area of the overlapping region between the encapsulation unit 8 and the isolation structure 7 is less than or equal to 50 (e.g. the ratio may be 50, 45, 40, 35, 30, 25, 20, or 15, etc.), the encapsulation unit 8 is less likely to fall off, thereby improving the encapsulation effect of the first encapsulation unit 81 on the first light-emitting unit, and further enhancing the display effect of the display panel.

In some possible implementations, the ratio of the area of the encapsulation unit 8 to the area of the overlapping region between the encapsulation unit 8 and the isolation structure 7 may be less than or equal to 35. For example, the ratio may be 35, 30, 25, 20, or 15, etc. Thus, the stability of the encapsulation unit 8 may further be improved.

At least part of the encapsulation unit 8 extends from a side, facing the isolation opening 9, of the isolation structure 7, to a side, facing away from the base plate 1, of the isolation structure 7. The encapsulation unit 8 includes an edge encapsulating portion 802 and an encapsulation portion 801 connected to each other. The edge encapsulating portion 802 is located on a side, facing away from the base plate 1, of the isolation structure 7. The encapsulation portion 801 is located in the isolation opening 9. A ratio of an area of an orthogonal projection of the encapsulation portion 801 on the base plate 1 to a perimeter of an orthogonal projection of an isolation opening 9 corresponding to the encapsulation portion 801 on the base plate 1 is less than or equal to 45. For example, the ratio may be 40, 35, 30, 25, 20, or 15, etc. Thus, the stability of the encapsulation unit 8 may further be improved.

The ratio of the area of the encapsulation portion 801 to the area of the overlapping region between the encapsulation portion 801 and the isolation structure 7 may be less than or equal to 30. For example, the ratio may be 30, 28, 25, 23, 20, 17, or 15, etc. Thus, the stability of the encapsulation unit 8 may further be improved.

In a same encapsulation unit 8, a ratio of the area of the encapsulation portion 801 to an area of the edge encapsulating portion 802 may be less than or equal to 10. For example, the ratio may be 10, 8, 5, 3 or 2, etc. Thus, the stability of the encapsulation unit 8 may further be improved.

Other technical solutions of the display panel in the present embodiment are the same as the technical solutions of the display panel in the above embodiments, which will be repeated herein again.

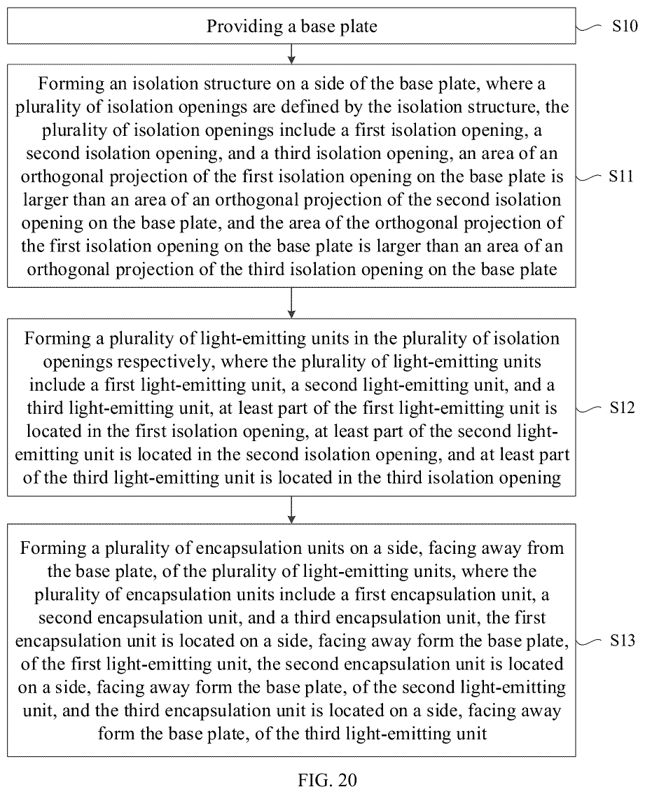

In some possible implementations, referring to FIG. 20, the present disclosure further provides a manufacturing method for a display panel. The method includes the following steps.

Step S10: providing a base plate.

Step S11: forming an isolation structure on a side of the base plate, where a plurality of isolation openings are defined by the isolation structure, the plurality of isolation openings include a first isolation opening, a second isolation opening, and a third isolation opening, an area of an orthogonal projection of the first isolation opening on the base plate is larger than an area of an orthogonal projection of the second isolation opening on the base plate, and the area of the orthogonal projection of the first isolation opening on the base plate is larger than an area of an orthogonal projection of the third isolation opening on the base plate.

Step S12: forming a plurality of light-emitting units in the plurality of isolation openings respectively, where the plurality of light-emitting units include a first light-emitting unit, a second light-emitting unit, and a third light-emitting unit, at least part of the first light-emitting unit is located in the first isolation opening, at least part of the second light-emitting unit is located in the second isolation opening, and at least part of the third light-emitting unit is located in the third isolation opening.

Step S13: forming a plurality of encapsulation units on a side, facing away from the base plate, of the plurality of light-emitting units, where the plurality of encapsulation units include a first encapsulation unit, a second encapsulation unit, and a third encapsulation unit, the first encapsulation unit is located on a side, facing away from the base plate, of the first light-emitting unit, the second encapsulation unit is located on a side, facing away from the base plate, of the second light-emitting unit, and the third encapsulation unit is located on a side, facing away from the base plate, of the third light-emitting unit.

Therein, a ratio of an area of an orthogonal projection of the first encapsulation unit 81 on the base plate 1 to a perimeter of the orthogonal projection of the first isolation opening 91 on the base plate 1 is a first ratio, a ratio of an area of an orthogonal projection of the second encapsulation unit 82 on the base plate 1 to a perimeter of the orthogonal projection of the second isolation opening 92 on the base plate 1 is a second ratio, and a ratio of an area of an orthogonal projection of the third encapsulation unit 83 on the base plate 1 to a perimeter of the orthogonal projection of the third isolation opening 93 on the base plate 1 is a third ratio. The first ratio is less than or equal to a sum of the second ratio and the third ratio.

Light emitted by the first light-emitting unit, the second light-emitting unit, and the third light-emitting unit, which are formed by the method mentioned above, is different from each other in color. For example, a color of light emitted by the first light-emitting unit includes red, a color of light emitted by the second light-emitting unit includes green, and a color of light emitted by the third light-emitting unit includes blue. Generally, the area of the orthogonal projection of the first isolation opening 91 corresponding to the first light-emitting unit on the base plate 1 is larger than both the area of the orthogonal projection of the second isolation opening 92 corresponding to the second light-emitting unit on the base plate 1 and the area of the orthogonal projection of the third isolation opening 93 corresponding to the third light-emitting unit on the base plate 1

The larger an area of the isolation opening 9 is, the larger an area of the encapsulation unit 8 covering the isolation opening 9 is. Therefore, generally, the area of the orthogonal projection of the first encapsulation unit 81 on the base plate 1 is greater than both the area of the orthogonal projection of the second encapsulation unit 82 and the area of the orthogonal projection of the third encapsulation unit 83 on the base plate 1.

A larger area for the encapsulation unit 8 leads to greater external scouring forces and a higher probability of detachment. Therefore, the first encapsulation unit 81 typically experiences greater external scouring force than the second encapsulation unit 82 and the third encapsulation unit 83, and the first encapsulation unit 81 is relatively more likely to fall off compared with the second encapsulation unit 82 and the third encapsulation unit 83.

In addition, a larger perimeter for the orthogonal projection of the isolation opening 9 on the base plate 1 leads to a greater contact area between the encapsulation unit 8 and the isolation structure 7, stronger adhesive force between the encapsulation unit 8 and the isolation structure 7, and less possibility for the encapsulation unit 8 to fall off.

In view of above, stability of the encapsulation unit 8 is related to the perimeter of the orthogonal projection of the isolation opening 9 on the base plate 1, as well as the area of the orthogonal projection of the encapsulation unit 8 on the base plate 1

After a long-term research, the inventors found that in the display panel, stability of the second encapsulation unit 82 and the third encapsulation unit 83 is relatively better and are less likely to fall off under the external force. Therefore, based on the second encapsulation unit 82 and the third encapsulation unit 83, when the first ratio is less than or equal to the sum of the second ratio and the third ratio, the stability of the first encapsulation unit 81 may be ensured, thereby enabling the first encapsulation unit 81 to provide better encapsulation effect for the first light-emitting unit. As a result, the first light-emitting unit is less likely to develop dark spots, thereby improving a display effect of the display panel.

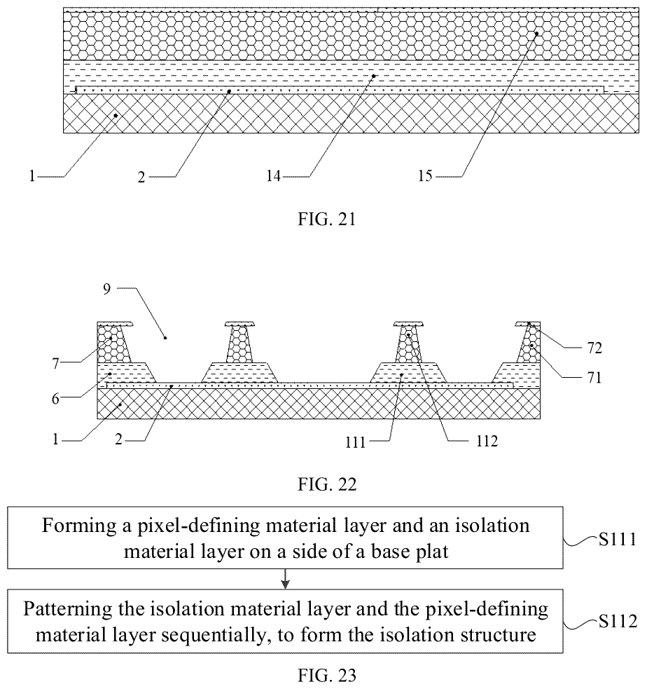

In some possible implementations, referring to FIGS. 21 to 23 the step of forming the isolation structure on the side of the base plate includes the following steps.

S111: forming a pixel-defining material layer and an isolation material layer on a side of a base plate.

S112: patterning the isolation material layer and the pixel-defining material layer sequentially, to form the isolation structure, a reinforcement block, and a pixel defining layer. The reinforcement block 11 is located in the isolation opening and contacts with the encapsulation unit 8.

A first reinforcement portion 111 may be formed simultaneously with the pixel defining layer 6, and a second reinforcement portion 112 may be formed simultaneously with the isolation structure 7 through the method mentioned above. Therefore, there is no need for a process of forming the first reinforcement portion 111 and the second reinforcement portion 112, thereby reducing the process cost of forming the reinforcement block 11.

In some possible implementations, the present disclosure further provides a display device. The display device includes the display panel as described in the present disclosure, or includes the display panel obtained by the manufacturing method for the display panel described in the present disclosure. The display device may include devices with image processing capabilities, such as a server, a personal computer, a laptop, etc. Since the display device includes the display panel of the present disclosure, the display quality of the display device is better.

The technical features of the above-described embodiments may be combined in any way. For the sake of conciseness, not every possible combination of the individual technical features has been described; nevertheless, any combination that does not give rise to contradiction shall be regarded as falling within the scope of the present disclosure.

The embodiments described above only express several implementations of the present disclosure. The descriptions are relatively specific and detailed, but should not be understood as a limitation on the scope of the invention patent. It should be pointed out that for those of ordinary skill in the art, several modifications and improvements can still be made without departing from the concept of the present invention, and these all fall within the scope of protection of the present invention. Therefore, the scope of protection of the present disclosure should be determined by the protection scope of the claims.

What is claimed is:

1. A display panel, comprising:
a base plate;
an isolation structure located on a side of the base plate, wherein a plurality of isolation openings are defined by the isolation structure, the plurality of isolation openings comprise a first isolation opening, a second isolation opening, and a third isolation opening, an area of an orthogonal projection of the first isolation opening on the base plate is larger than an area of an orthogonal projection of the second isolation opening on the base plate, and an area of an orthogonal projection of the first isolation opening on the base plate is larger than an area of an orthogonal projection of the third isolation opening on the base plate;
a plurality of light-emitting units, wherein the plurality of light-emitting units comprise a first light-emitting unit, a second light-emitting unit, and a third light-emitting unit, at least part of the first light-emitting unit is located in the first isolation opening, at least part of the second light-emitting unit is located in the second isolation opening, and at least part of the third light-emitting unit is located in the third isolation opening; and
a plurality of encapsulation units, wherein the plurality of encapsulation units comprise a first encapsulation unit, a second encapsulation unit, and a third encapsulation unit, the first encapsulation unit is located on a side, facing away from the base plate, of the first light-emitting unit, the second encapsulation unit is located on a side, facing away from the base plate, of the second light-emitting unit, and the third encapsulation unit is located on a side, facing away from the base plate, of the third light-emitting unit;
wherein a ratio of an area of an orthogonal projection of the first encapsulation unit on the base plate to a perimeter of the orthogonal projection of the first isolation opening on the base plate is a first ratio, a ratio of an area of an orthogonal projection of the second encapsulation unit on the base plate to a perimeter of the orthogonal projection of the second isolation opening on the base plate is a second ratio, a ratio of an area of an orthogonal projection of the third encapsulation unit on the base plate to a perimeter of the orthogonal projection of the third isolation opening on the base plate is a third ratio, and the first ratio is less than or equal to a sum of the second ratio and the third ratio.

2. The display panel according to claim 1, wherein a ratio of an area of an orthogonal projection of an encapsulation unit on the base plate to a perimeter of an orthogonal projection of an isolation opening corresponding to the encapsulation unit on the base plate is less than or equal to 50.

3. The display panel according to claim 2, wherein at least part of the encapsulation unit extends from a side, facing the isolation opening, of the isolation structure, to a side, facing away from the base plate, of the isolation structure, the encapsulation unit comprises an edge encapsulating portion and an encapsulation portion connected to each other; the edge encapsulating portion is located on the side, facing away from the base plate, of the isolation structure, the encapsulation portion is located in the isolation opening, a ratio of an area of an orthogonal projection of the encapsulation portion on the base plate to the perimeter of the orthogonal projection of the isolation opening corresponding to the encapsulation portion on the base plate is less than or equal to 45;
a gap exists between a side, closer to the base plate, of the edge encapsulating portion, and the side, facing away from the base plate, of the isolation structure;
light emitted by the first light-emitting unit, the second light-emitting unit, and the third light-emitting unit is different from each other in color;
a shape of the orthogonal projection of the isolation opening on the base plate comprises at least one of a rectangular shape and a rectangle-like shape; and
the rectangular shape comprises at least one of a rectangle and a square, and the rectangle-like shape comprises at least one of a rectangle with chamfered corners or a rectangle with rounded corners.

4. The display panel according to claim 1, wherein the first ratio is greater than the second ratio, and the first ratio is greater than the third ratio.

5. The display panel according to claim 1, wherein an isolation opening comprises at least two sub-isolation openings, a light-emitting unit comprises at least two sub-light-emitting units, the sub-light-emitting unit is located in the sub-isolation opening, an encapsulation unit covers a plurality of sub-light-emitting units located in the same isolation opening and is in connect with the isolation structure located between two adjacent sub-isolation openings;
the encapsulation unit comprises a sub-encapsulation portion located in the sub-isolation opening; a ratio of an area of an orthogonal projection of the sub-encapsulation portion on the base plate to a perimeter of an orthogonal projection of the sub-isolation opening corresponding to the sub-encapsulation portion on the base plate is less than or equal to 45;
the encapsulation unit covers the isolation structure located between the two adjacent sub-isolation openings;
a width of an orthogonal projection of the isolation structure located between the two adjacent sub-isolation openings on the base plate is greater than or equal to 3 μm and less than or equal to 6 μm;
light emitted by the sub-light-emitting units located within the same isolation opening is of a same color; and
a shape of an orthogonal projection of the sub-isolation opening on the base plate comprises at least one of a rectangle and a square.

6. The display panel according to claim 5, wherein the light-emitting unit comprises a first electrode, a light-emitting portion, and a second electrode sequentially stacked in a direction away from the base plate, the isolation structure comprises a first isolation portion and a second isolation portion sequentially stacked in the direction away from the base plate, and the second electrode is electrically connected to the first isolation portion;
the light-emitting portion comprises a plurality of sub-light-emitting portions spaced apart, the second electrode comprises a plurality of second sub-electrodes spaced apart, the sub-light-emitting unit comprises a sub-light-emitting portion and a second sub-electrode, the plurality of sub-light-emitting units located within the same isolation opening share the same first electrode; or the first electrode comprises a plurality of first sub-electrodes spaced apart, and the plurality of sub-light-emitting units comprise the plurality of first sub-electrodes;
the base plate comprises a substrate, a conductive layer and an insulating layer sequentially stacked on a side of the substrate, a plurality of via holes extending through the insulating layer are provided in the insulating layer, a first sub-electrode is electrically connected to the conductive layer through a via hole; and
the first isolation opening comprises at least two first sub-isolation openings, the first light-emitting unit comprises at least two first sub-light-emitting units, the first sub-light-emitting unit is located in the first sub-isolation opening.

7. The display panel according to claim 1, wherein the first encapsulation unit comprises a first edge encapsulating portion located on a side, facing away from the base plate, of the isolation structure, the second encapsulation unit comprises a second edge encapsulating portion located on the side, facing away from the base plate, of the isolation structure, and along an arrangement direction of the first isolation opening and the second isolation opening, an extension length of the first edge encapsulating portion is less than an extension length of the second edge encapsulating portion;
the third encapsulation unit comprises a third edge encapsulating portion located on the side, facing away from the base plate, of the isolation structure, and along an arrangement direction of the first isolation opening and the third isolation opening, an extension length of the first edge encapsulating portion is less than an extension length of the third edge encapsulating portion; and
along the arrangement direction of the first isolation opening and the second isolation opening, the extension length of the first edge encapsulating portion is greater than or equal to 1 μm and less than or equal to 6 μm.

8. The display panel according to claim 7, wherein a gap exists between a side, facing the base plate, of the first edge encapsulating portion, and the side, facing away from the base plate, of the isolation structure;
a gap exists between a side, closer to the base plate, of the second edge encapsulating portion, and the side, facing away from the base plate, of the isolation structure;
a gap exists between a side, closer to the base plate, of the third edge encapsulating portion, and the side, facing away from the base plate, of the isolation structure;
the first edge encapsulating portion at least partially overlap with the second edge encapsulating portion, the first edge encapsulating portion is located on the side, facing the base plate, of the second edge encapsulating portion; and
the first edge encapsulating portion at least partially overlap with the third edge encapsulating portion, and the first edge encapsulating portion is located on the side, facing the base plate, of the third edge encapsulating portion.

9. The display panel according to claim 1, wherein the isolation structure comprises a first isolation portion and a second isolation portion sequentially stacked in the direction away from the base plate, a side wall, facing the isolation opening, of the isolation structure is provided with a concave-convex structure, and an encapsulation unit is in contact with the concave-convex structure;
the concave-convex structure comprises a first concave-convex structure located on a side, facing an isolation opening, of the first isolation portion;
the concave-convex structure comprises a second concave-convex structure located on a side, facing the isolation opening, of the second isolation portion;
the first concave-convex structure is serrated; and
the encapsulation unit is mutually embedded with the concave-convex structure.

10. The display panel according to claim 1, further comprising a reinforcement block located in an isolation opening, an encapsulation unit is in contact with the reinforcement block;
the encapsulation unit extends from a side wall, facing the isolation structure, of the reinforcement block, to a side, facing away from the base plate, of the reinforcement block;
the encapsulation unit covers the reinforcement block;
an orthogonal projection of the reinforcement block on the base plate is located outside an orthogonal projection of the isolation structure on the base plate; and
a quantity of the reinforcement blocks is greater than one.

11. The display panel according to claim 10, wherein the reinforcement block comprises a first reinforcement portion and a second reinforcement portion arranged along the direction away from the base plate, the second reinforcement portion is provided in a same layer as the isolation structure;
the second reinforcement portion has a same structure of layers as the isolation structure, and material of layers of the second reinforcement portion is the same as the isolation structure;
wherein the display panel further comprises a pixel defining layer located between the base plate and the isolation structure, a plurality of pixel openings are provided in the pixel defining layer, and a pixel opening is in communication with the isolation opening;
the first reinforcement portion is provided in a same layer as the pixel defining layer;
a material of the first reinforcement portion is the same as a material of the pixel defining layer; and
the orthogonal projection of the reinforcement block on the base plate is located outside an orthogonal projection of the pixel defining layer on the base plate.

12. The display panel according to claim 1, wherein the isolation structure comprises a first isolation portion and a second isolation portion sequentially stacked in the direction away from the base plate, a minimum distance between an edge of an orthogonal projection of a side, facing away from the base plate, of the first isolation portion corresponding to the first light-emitting unit on the base plate and an edge of an orthogonal projection of a side, facing the base plate, of the second isolation portion corresponding to the first light-emitting unit on the base plate is a first distance, a minimum distance between an edge of an orthogonal projection of a side, facing away from the base plate, of the first isolation portion corresponding to the second light-emitting unit on the base plate and an edge of an orthogonal projection of a side, closer to the base plate, of the second isolation portion corresponding to the second light-emitting unit on the base plate is a second distance, and the first distance is greater than the second distance;
a minimum distance between an edge of an orthogonal projection of a side, facing away from the base plate, of the first isolation portion corresponding to the third light-emitting unit on the base plate, and an edge of an orthogonal projection of a side, facing the base plate, of the second isolation portion corresponding to the third light-emitting unit on the base plate is a third distance, and the first distance is greater than the third distance; and
the first distance is greater than or equal to 0.3 μm and less than or equal to 0.7 μm.

13. The display panel according to claim 1, wherein the isolation structure comprises a first isolation portion and a second isolation portion sequentially stacked along a direction away from the base plate, an orthogonal projection of a side, facing away from the base plate, of the first isolation portion on the base plate, is located within an orthogonal projection of the second isolation portion on the base plate, a second electrode of the light-emitting unit is electrically connected to the first isolation portion; and
a plurality of first openings are defined by a side, facing away from the base plate, of the first isolation portion, the first openings comprises a first sub-opening, a second sub-opening, and a third sub-opening, an area of an orthogonal projection of the first sub-openings on the base plate is larger than an area of an orthogonal projection of the second sub-opening on the base plate, the area of the orthogonal projection of the first sub-opening on the base plate is larger than an area of an orthogonal projection of the third sub-opening on the base plate, at least part of the first light-emitting unit is located in the first sub-opening, at least part of the second light-emitting unit is located in the second sub-opening, and at least part of the third light-emitting unit is located in the third sub-opening.

14. The display panel according to claim 13, wherein a ratio of the area of the orthogonal projection of the first encapsulation unit on the base plate to a perimeter of an orthogonal projection of the first sub-opening on the base plate is a tenth ratio, a ratio of the area of the orthogonal projection of the second encapsulation unit on the base plate to a perimeter of an orthogonal projection of the second sub-opening on the base plate is a eleventh ratio, a ratio of the area of the orthogonal projection of the third encapsulation unit on the base plate to a perimeter of an orthogonal projection of the third sub-opening on the base plate is a twelfth ratio, and the tenth ratio is less than or equal to a sum of the eleventh ratio and the twelfth ratio;
the isolation structure further comprises a third isolation portion located on a side, facing the base plate, of the first isolation portion, a second electrode of the light-emitting unit is electrically connected to the third isolation portion;
a material of the third isolation portion comprises Mo, a material of the first isolation portion comprises Al, and a material of the second isolation portion comprises Ti;
the display panel further comprises a first encapsulation layer, a second encapsulation layer located on a side, facing away from the base plate of the first encapsulation layer, and a third encapsulation layer located on a side, facing away from the base plate of the second encapsulation layer.

15. A display panel, comprising:
a base plate;
an isolation structure located on a side of the base plate, wherein the isolation structure comprises a first isolation portion and a second isolation portion sequentially stacked along a direction away from the base plate, a plurality of isolation openings are defined by the second isolation portion, the plurality of isolation openings comprise a first isolation opening, a second isolation opening, and a third isolation opening, an area of an orthogonal projection of the first isolation opening on the base plate is larger than an area of an orthogonal projection of the second isolation opening on the base plate, the area of the orthogonal projection of the first isolation opening on the base plate is larger than an area of an orthogonal projection of the third isolation opening on the base plate;
a plurality of light-emitting units, wherein the plurality of light-emitting units comprise a first light-emitting unit, a second light-emitting unit, and a third light-emitting unit, at least part of the first light-emitting unit is located in the first isolation opening, at least part of the second light-emitting unit is located in the second isolation opening, and at least part of the third light-emitting unit is located in the third isolation opening; and
a plurality of encapsulation units, wherein the plurality of encapsulation units comprise a first encapsulation unit, a second encapsulation unit, and a third encapsulation unit, the first encapsulation unit is located on a side, facing away from the base plate, of the first light-emitting unit, the second encapsulation unit is located on a side, facing away from the base plate, of the second light-emitting unit, and the third encapsulation unit is located on a side, facing away from the base plate, of the third light-emitting unit;
wherein a ratio of an area of the first encapsulation unit to an area of an overlapping region between the first encapsulation unit and the isolation structure is a fourth ratio, a ratio of an area of the second encapsulation unit to an area of an overlapping region between the second encapsulation unit and the isolation structure is a fifth ratio, a ratio of an area of the third encapsulation unit to an area of an overlapping region between the third encapsulation unit and the isolation structure is a sixth ratio, and the fourth ratio is less than or equal to a sum of the fifth ratio and the sixth ratio.

16. The display panel according to claim 15, wherein the fourth ratio is greater than the fifth ratio, and the fourth ratio is greater than the sixth ratio;
the fourth ratio is less than or equal to 50, the fifth ratio is less than or equal to 50, and the sixth ratio is less than or equal to 50;
a ratio of an area of an orthogonal projection of the first encapsulation unit on the base plate to the area of the overlapping region between the first encapsulation unit and the isolation structure is a seventh ratio, a ratio of an area of an orthogonal projection of the second encapsulation unit on the base plate to the area of the overlapping region between the second encapsulation unit and the isolation structure is an eighth ratio, a ratio of an area of an orthogonal projection of the third encapsulation unit on the base plate to the area of the overlapping region between the third encapsulation unit and the isolation structure is a ninth ratio, and the seventh ratio is less than or equal to a sum of the eighth ratio and the ninth ratio; and
the seventh ratio is greater than the eighth ratio, and the seventh ratio is greater than the ninth ratio.

17. The display panel according to claim 15, wherein a side wall, facing the isolation opening, of the isolation structure is provided with a concave-convex structure, an encapsulation unit is in contact with the concave-convex structure;
the concave-convex structure comprises a first concave-convex structure located on a side, facing the isolation opening, of the first isolation portion;
the concave-convex structure comprises a second concave-convex structure located on a side, facing the isolation opening, of the second isolation portion;
the first concave-convex structure is serrated; and
the encapsulation unit is mutually embedded with the concave-convex structure.

18. The display panel according to claim 15, further comprising a plurality of reinforcement blocks, one of the plurality of reinforcement blocks is located in an isolation opening, an encapsulation unit is in contact with the reinforcement block;
the encapsulation unit extends from a side wall, facing the isolation structure, of the reinforcement block, to a side, facing away from the base plate, of the reinforcement block;
the encapsulation unit covers the reinforcement block;
an orthogonal projection of the reinforcement block on the base plate is located outside an orthogonal projection of the isolation structure on the base plate; and
a quantity of the reinforcement blocks is greater than one.

19. The display panel according to claim 18, wherein the reinforcement blocks comprises a first reinforcement portion and a second reinforcement portion arranged along the direction away from the base plate, and the second reinforcement portion is provided in a same layer as the isolation structure;
the second reinforcement portion has a same structure of layers as the isolation structure, and material of layers of the second reinforcement portion is the same as the isolation structure;
wherein the display panel further comprises a pixel defining layer located between the base plate and the isolation structure, a plurality of pixel openings are provided in the pixel defining layer, and a pixel opening is in communication with the isolation opening;
the first reinforcement portion is provided in a same layer as the pixel defining layer;
a material of the first reinforcement portion is the same as a material of the pixel defining layer; and
the orthogonal projection of the reinforcement block on the base plate is located outside an orthogonal projection of the pixel defining layer on the base plate.

20. A display device, comprising the display panel according to claim 1.
